(19) United States
(12) Patent Application Publication
(10) Pub. No.: US 2025/0105089 A1
(43) Pub. Date: Mar. 27, 2025

(54) HOTSPOT-FREE SEMICONDUCTOR DEVICE CHIPS

(71) Applicant: Diamond Foundry Inc., South San Francisco, CA (US)

(72) Inventors: Jeroen Van Duren, Fremont, CA (US); Martin Roscheisen, San Francisco, CA (US)

(21) Appl. No.: 18/761,091

(22) Filed: Jul. 1, 2024

Related U.S. Application Data
(63) Continuation-in-part of application No. PCT/US23/86169, filed on Dec. 28, 2023.
(60) Provisional application No. 63/539,983, filed on Sep. 22, 2023.
(60) Provisional application No. 63/539,983, filed on Sep. 22, 2023.

(51) Int. Cl. H01L 23/373; H01L 23/00

(52) U.S. Cl. CPC H01L 23/3732; H01L 24/08; H01L 24/27; H01L 24/32; H01L 24/80; H01L 24/83; H01L 2224/08225; H01L 2224/2745; H01L 2224/32225; H01L 2224/8001; H01L 2224/8009; H01L 2224/80896; H01L 2224/83022; H01L 2224/8309; H01L 2224/83193

(57) ABSTRACT

A method of making an integrated circuit device with a diamond heat spreader including one or more integrated circuit (IC) devices in a semiconductor material and bonding one or more diamond layers. A device may comprise one or more integrated circuit (IC) devices in a semiconductor material thinner than 100 micrometers and one or more diamond layers of thickness up to 2000 micrometers bonded to the semiconductor material.

### CROSS-REFERENCE TO RELATED APPLICATION

This application claims the priority benefit of U.S. Provisional Patent Application No. 63/539,983 to Jeroen K. J. Van Duren and Martin R. Roscheisen, filed Sep. 22, 2023, the entire contents of which are incorporated herein by reference. This application is also a continuation-in-part of International Patent Application Number PCT/US23/86169 filed Dec. 28, 2023, the entire contents of which are incorporated herein by reference. International Patent Application Number PCT/US24/30242 also claims the priority benefit of U.S. Provisional Patent Application No. 63/539,983, filed Sep. 22, 2023.

### FIELD OF THE DISCLOSURE

Aspects of the present disclosure relate to semiconductor devices and more particularly to semiconductor devices having a device die directly bonded to a single crystal diamond substrate to reduce hot spots.

### BACKGROUND

It is well known that diamond conducts heat very well and can serve as a heat spreader in electronics devices. This holds for both single crystal and polycrystalline diamond. However, the practical challenges and potential of integrating diamond, whether single crystal diamond (SCD) or polycrystalline diamond (PCD), with semiconductor devices and/or integrated circuits (IC) have not been fully appreciated. Growing PCD on the back of a semiconductor wafer (prior to device processing) typically results in excessive wafer warpage, and poor effective thermal barrier resistance between the wafer and the large grains of PCD film or a (polycrystalline or nanocrystalline) diamond film with a low thermal conductivity. Growth of PCD on the back of an IC or device wafer (after device processing) typically results in excessive wafer warpage and damage to the devices in addition to the poor effective thermal barrier resistance or a (polycrystalline or nanocrystalline) diamond film with a low thermal conductivity. The same holds when depositing PCD on the front of a semiconductor (device) wafer. Bonding PCD wafers (instead of growing PCD films) is challenging due to the difficulty in smoothening PCD. Epitaxial growth of semiconductors onto SCD or PCD has proven extremely difficult and requires thermally limiting buffer layers. Another limiting factor is the use of a Thermal Interface Material (TIM) between the diamond (whether SCD or PCD) and IC or device chips. The TIM adds a thermal barrier resistance (TBR) that reduces the transfer of heat from the IC chip to the SCD die. Another limiting factor is the need for a minimum thickness of the silicon for mechanical stability. Thinner silicon will result in a lower thermal resistance. Furthermore, there are process limitations to ensure high yield manufacturing when integrating diamond, both temperature and force limitations, e.g. to ensure compatibility with temporary adhesives, fragile stacks, or vertical interconnect materials. Alignment accuracy benefits from low temperature processing, especially when dealing with vertical interconnects. In addition, the diamond integration method needs to withstand downstream process conditions, e.g. reflow temperatures. As such, there is a need for a low-temperature, low-force process to integrate ultrathin silicon without the use of a thick, thermally-limiting intermediate layer to a highly efficient heat spreader that provides sufficient mechanical stability. Furthermore, depending on the required performance enhancement provided by the heat spreader, there is a need for a low cost heat spreader integration method. The cost reduction benefits from reduced diamond smoothening and reduced diamond thickness. The thin intermediate layer needs to be either ultrathin or needs to have a high thermal conductivity with minimal interfaces. In addition, in case the heat spreader has through-holes for vertical interconnects, there is a need for an integration method with electrically resistive thin intermediate layers. It is within this context that aspects of the present disclosure arise.

### BRIEF DESCRIPTION OF DRAWINGS

FIG. 1 is a cross-sectional schematic diagram of a composition of matter having a semiconductor material directly bonded to a single crystal diamond material in accordance with aspects of the present disclosure.

FIG. 2 is a cross-sectional transmission electron microscopy (TEM) image illustrating a direct bonded interface between a semiconductor material and a single crystal diamond material in accordance with aspects of the present disclosure.

FIG. 3 is a cross-sectional schematic diagram of a device having a semiconductor device die directly bonded to a single crystal diamond thermal management material in accordance with aspects of the present disclosure.

FIG. 4 is a cross-sectional schematic diagram of a device having a bumped semiconductor device die directly bonded to a single crystal diamond material in accordance with aspects of the present disclosure.

FIG. 5 is a cross-sectional schematic diagram of a device having a semiconductor wafer with a plurality of bumped semiconductor device dies directly bonded to a single crystal diamond material in accordance with aspects of the present disclosure.

FIG. 6 is a cross-sectional schematic diagram of a device having a semiconductor wafer with a plurality of bumped semiconductor device dies with a corresponding plurality of diamond substrates directly bonded to the semiconductor wafer in accordance with aspects of the present disclosure.

FIGS. 7A-7G illustrate an example of fabrication of a composition of matter having a semiconductor material directly bonded to a single crystal diamond material in accordance with aspects of the present disclosure.

FIGS. 7H-7K illustrate an example of fabrication of compositions of matter having semiconductor materials directly bonded to corresponding single crystal diamond materials in a collective-die-to-collective-die (CD2CD) configuration in accordance with aspects of the present disclosure.

FIGS. 8A-8C illustrate examples of direct bonding a semiconductor material to a single crystal diamond material in accordance with aspects of the present disclosure.

FIGS. 8D-8F illustrate examples of hybrid bonding a semiconductor material with metal region to a single crystal diamond material with metal region in accordance with aspects of the present disclosure.

FIGS. 9A-9F illustrate an example of fabrication of a composition of matter having a semiconductor material having integrated circuit devices formed therein directly bonded to a single crystal diamond substrate having through diamond vias according to aspects of the present disclosure.

FIGS. 9G-9J illustrate an example of fabrication of a composition of matter having a semiconductor material having integrated circuit devices formed therein with a diamond layer introduced after BEOL.

FIGS. 10A-10C depict an example method of making a composition of matter having frontside and backside semiconductor interconnects and frontside and backside single crystal diamond material directly bonded to the semiconductor substrate according to aspects of the present disclosure.

FIGS. 11A-11C depict a method of making a composition of matter of an integrated circuit device having a backside and frontside SCD heat spreader bonded to the semiconductor substrate underneath the backside and frontside interconnects respectively according to aspects of the present disclosure.

FIGS. 12A-12G depict a method of making a composition of matter of semiconductor substrate having a diamond interconnect directly bonded to a major surface according to aspects of the present disclosure.

FIG. 13 depicts a composition of matter of a semiconductor substrate directly bonded to a frontside diamond interconnect and a backside diamond interconnect according to aspects of the present disclosure.

FIGS. 14A-14C depict 3-dimensional stacked IC devices according to aspects of the present disclosure.

### DEFINITIONS

In the detailed description below, certain terms have the following meanings.

Die refers to a plate or coupon, rectangular or square, sometimes diced out of a wafer.

Device may refer to a machine, a machine component, or a machine subcomponent for example and without limitation device may refer to a machine having an integrated circuit (e.g. a computer), an integrated circuit, or a component of an integrated circuit, such as a transistor, diode, light-emitting diode (LED), capacitor, (variable) resistor, laser, transformer, voltage regulator, antennas, oscillators, power amplifier, or inductor.

Device die refers to a die with one or more devices formed on it.

Chip refers to one or more semiconductor dies assembled into a package.

Integrated circuit (IC) refers to a set of electronic circuits on a semiconductor die or chip. In a typical IC, large numbers of miniaturized transistors and other electronic components are integrated together in a multi-layered (electrically) active patterned structure.

Wafer refers to a generally round disc of material serving as substrate, either resistive, doped, semiconductor, or dielectric. A wafer may have a notch or D-cut for alignment purposes.

Substrate may refer to a supporting material on which (or in which) a circuit may be formed or fabricated. For example, in some implementations the substrate may be comprised of a first semiconductor material and a second similar semiconductor material disposed on top (e.g. silicon on silicon) in which one or more IC devices are formed, or the second semiconductor material may be disposed on top of a significantly different composition of matter (e.g. gallium nitride on silicon).

Material refers to a composition of matter having specific chemical and physical properties.

Semiconductor refers to materials that can switch between conducting and insulating electricity, depending on temperature and chemical treatment. Semiconductors include elementary semiconductors and compound semiconductors. Elementary semiconductors are made up of single types of atoms, such as silicon (Si), germanium (Ge), and tin (Sn) in column IV, and selenium (Se) and tellurium (Te) in column VI of the periodic table. Compound semiconductors are made up of two or more elements, such as semiconductors that connect elements from groups III and V and elements from groups II and VI. Examples of compound semiconductors include Silicon Carbide, Silicon Germanium, Gallium Arsenide (GaAs), Indium Phosphide (InP), Gallium Nitride (GaN), Indium Gallium Aluminum Phosphide (InGaAlP), Cadmium Telluride (CdTe), chalcogenides, Zinc Oxide (ZnO), and Aluminum Nitride (AlN) alloys. Compound semiconductors have been used traditionally in high frequency devices, power devices, photovoltaic devices, and optical devices.

Bonded as used herein may refer to the secure coupling of at least two materials together. Bonding of the two materials may include any number of intervening layers of other materials between the two bonded materials. The intervening layers of other material may be located within an interfacial layer between the two materials. The interfacial layer may be comprised of one or more layers of distinct material from the two materials that are being bonded or the interfacial layer may be incorporated into the crystal structure of one or both of the materials that are being bonded together.

### DETAILED DESCRIPTION OF THE INVENTION

Single crystal diamond has very high thermal conductivity (2200 W/m-K at room temperature, even possible to grow >3000 W/m-K) and can therefore be used as an excellent heat spreader to mitigate thermal hotspots that limit the power capacity and thus speed (or operations per second) of integrated circuit (IC) chips, e.g. for compute or network chips, like GPU, TPU, CPU, ASIC, FPGA, System-on-Chip (SOC), or AI chips. But the extent to which this can have an impact has been vastly underestimated. Past efforts have targeted minor improvements (10's percentages) in power capacity. However, the present inventors have targeted a 10× improvement in power capacity using thin (e.g., <10 micron (μm)) semiconductor on diamond. According to aspects of the present disclosure, integration of diamond substrates into devices may be eased through the use of thick diamond substrates (e.g., >500 microns).

Only recently has it become clear how well silicon and diamond can be directly bonded together without any Thermal Interface Material (TIM) that would add to thermal resistance. Strong bonds can be formed between silicon and single crystal diamond, whether by surface activated bonding (SAB), atomic diffusion bonding (ADB), Plasma-Assisted Bonding (PAB), or Thermo-Compression Bonding (TCB). SAB and ADB allow bonding at low temperature (e.g. room temperature to 150° C.) which may improve alignment accuracy and may reduce thermal stress. Furthermore, SAB may result in strong bonds and very low thermal interface resistance. An additional advantage of SAB and ADB over PAB is the absence of water at the bondline. SAB may even be used without the use of any intermediate bond layers. However, both SAB and ADB are ultra-high vacuum methods which typically impact equipment cost, maintenance cost, and throughput. In addition, both SAB and ADB are wafer bond techniques requiring dies to be placed on a temporary wafer carrier with strict thickness requirements for the dies, e.g. for collective-dies-to-wafer (CD2 W) or collective-dies-to-collective-dies (CD2CD) bonding. Furthermore, SAB and ADB have strict roughness requirements (e.g. Sa<0.5 nm). Plasma-assisted bonding (PAB) of silicon substrates is commonly used in CMOS foundries for advanced packaging, e.g. hybrid bonding, with process temperatures from 150° C. to 400° C. PAB with dies may be performed by CD2 W, and CD2CD bonding, yet PAB may also be performed by sequential-dies-to-wafer (SD2 W) bonding or die-to-die bonding (D2D) using a pick-and-place (flip chip) die bonder. SD2 W (or D2D) may have less strict die thickness requirements and may not require bonding to a temporary carrier, which are both advantages. Furthermore, PAB may not require ultra-high vacuum. These are all benefits of PAB. However, the PAB bond relies on dielectric films (e.g. SiO₂ or SiCN) with a very low thermal conductivity (˜1 W/m-K) resulting in a relatively high thermal barrier resistance despite the relatively low film thickness of 100's nanometers. Thus, there is a need to reduce the thermal resistance for PAB by further thinning the bond layers and/or increasing the thermal conductivity of these bond layers. Furthermore, PAB has strict roughness requirements (e.g. Sa<0.5 nm). Thermo-compression bonding (TCB) historically is mainly used for vertical interconnects and perimeter sealing (e.g. MEMS) with silicon at temperatures of 300° C. to 500° C. and requires significant force (e.g. 10's MPa). Typical bondline thickness for TCB is in the micrometer range (e.g. 1-10 micrometers). TCB is typically slow, which may make it less suitable for SD2 W or D2D bonding and more suitable for bonding in a wafer bonder, e.g. CD2 W or CD2CD. TCB's roughness requirements are less strict (e.g. Sa<3 nm). Process temperature and force in TCB may be reduced by improved smoothness, flatness, and cleanliness of the metal surfaces. Improved smoothness, flatness, and cleanliness may also allow for thinner films. Furthermore, coefficient-of-thermal expansion (CTE) matching of the diamond and semiconductor may allow a further thickness reduction of the metal films. As such, the similar CTE for silicon and diamond may be very beneficial for a further (bond) film thickness reduction. Common materials used for metal bonding are gold and copper. Process temperature and force reduction may allow for fragile stacks (e.g. avoiding device, lateral or vertical interconnect damage), compatibility with temporary adhesives, alignment accuracy improvement, reduced warpage, reduced thermal stress, etc. TCB is a form of metal bonding that involves solids only. Metal bonding that involves a liquid includes solder bonding, eutectic bonding, and transient liquid phase bonding (TLPB). These liquid-based forms of metal bonding have the added benefit of further lowering temperature (e.g. 180° C. to 300° C.) and force requirements (e.g. <1 MPa), and reduced roughness requirements (e.g. Sa<100 nm). In addition, organic or polymer bonding involves deposition of a precursor, molecule, monomer, oligomer, or polymer on one or two surfaces followed by bonding. Curing (e.g. cross linking) may be based on heat, irradiation (e.g. UV), or water for adhesives, or based on cooldown for thermoplastic materials. The thickness of organic bondline may be 100 nm, or as thin as 5 nm. Deposition may be performed by spin coating, spraying, dipping, or jetting. Materials may be epoxies, photoresists, benzocyclobutene (BCB) derivatives, spin-on photo-dielectrics, silicones, or polyimides. Similarly, spin-on glass or polymer-derived ceramics may be used, e.g. polysilazane derivatives (e.g. polyborosilazane), polysiloxane derivatives, polysilane derivatives (e.g. polycarbosilane), polysilsesquioxanes, polysilsesquiazanes, polysilylcarbodiimides, etc. These materials may be filled with nano-sized materials with a high thermal conductivity (and lower CTE), e.g. diamond nanopowder, AlN nanopowder, SiNₓ nanopowder, BeO nanopowder, Al₂O₃ nanopowder, graphite, carbon nanotubes, graphene, etc. As mentioned previously, bonding of diamond dies may be performed die to die, sequential-dies-to-wafer, collective-dies-to-wafer, collective dies to collective dies, meaning wafer-sized diamond (e.g., SCD) substrates are not necessary. Instead, thermal management may be implemented with die-sized (or larger) SCD plates that are commercially available from Diamond Foundry Inc. of South San Francisco, California. The availability of single crystal diamond in die sized plates up to the reticle limit (for example and without limitation 33×26 mm) greatly facilitates integration of SCD substrates with IC device dies in accordance with aspects of the present disclosure. In implementations that bond the semiconductor to diamond there may be one clear interface between the semiconductor and the SCD, in some implementations a transition from crystalline to amorphous on each side of the interface may also exist. Annealing may convert the amorphous material to a crystalline material. Furthermore, SAB may be implemented using one or more thin films at the bond interface. There may be two clear interfaces between semiconductor and SCD when bonding by ADB, albeit an interface between both films used for ADB may exist. This interface may be avoided by annealing. There may be at least 2 clear interfaces for PAB when depositing dedicated bond layers (films or bonding agents), albeit a compositional gradient may exist across the bond, e.g. for SiCN (oxide rich at interface). Furthermore, in implementations that add an adhesion or barrier layer onto the diamond, additional interfaces may be present. In implementations that bond diamond to silicon by PAB without the use of bond layers (films) on the diamond, at least one interface exists. In other implementations that use dedicated bond layers with PAB to bond diamond to silicon at least 2 interfaces may exist. Potentially more interfaces than 2 interfaces may exist in implementations that also deposit adhesion or barrier layers onto the diamond. In implementations that use metal bonding to attach diamond to silicon, at least 2 interfaces may exist, but there may be in many such implementations more than two interfaces due to the use of adhesion and barrier layers.

Furthermore, it has recently become possible to process IC wafers in a way that thins a silicon or other semiconductor wafer to a few microns of residual passive silicon only and then bond it to Diamond Foundry's ultrasmooth single crystal diamond. The silicon of the IC wafers may even be thinned to less than 500 nm thick, or even less than 100 nm thick, e.g. by methods commonly used for backside power delivery. Earlier simulations for boost of power capacity have been performed using silicon that is 200 microns (μm) thick. Power capacity may be dramatically improved by thinning the semiconductor wafer to a thickness of 5-10 μm or less, preferably less than 250 nm thick, and bonding the remaining thickness of silicon to SCD substrate with an interfacial layer of 500 nm (nanometers) thick or less, 250 nm thick or less, 150 nm thick or less, 100 nm thick or less, 50 nm thick or less, 25 nm thick or less, preferably, 10 nm thick or less or even 5 nm thick or less, thickness may vary depending on the type of bonding and films. Thicker films (for example and without limitation films having a thickness in the order of magnitude of micrometers) may be used for metal bonds with a thermal conductivity of 100's W/m-K, e.g. copper, silver, or gold. Such thinning may be accomplished, e.g., by using one or more of the following techniques: abrasive techniques, grinding, lapping, chemical mechanical polishing (CMP), polishing (wet or dry), wet etching, dry etching, or laser ablation. The thinning process may be facilitated by, e.g., a temporary carrier with a temporary adhesive, specialized pads or tapes, or the TAIKO process. Instead of temporary carriers with temporary adhesives, mobile electrostatic carriers might be used. Furthermore, a temporary carrier may be bonded to the IC wafer without the use of a temporary adhesive, e.g. by PAB. In implementations that bond a temporary carrier by PAB, after thinning of the IC wafer and bonding to the diamond, the temporary carrier may be removed by e.g. grinding followed by etching and/or polishing. This means that a temporary carrier may be bonded by what is normally considered a permanent bond. The resulting composition may be a diamond die of, for example and without limitation less than 300 μm thickness with 5-10 μm of silicon on top, which may include p/n silicon and its transistors and interconnects. In a chip like this, there may no longer be any serious hotspots. Any heat that a transistor can generate may immediately dissipate in the diamond. In other words, the power capacity of such a chip can be increased by the factor that diamond is thermally more conductive than silicon. For Silicon with a thermal conductivity of 148 W/m-K and SCD with a thermal conductivity of 2200 W/m-K, there would potentially be roughly a factor of 15 improvement of power capacity. Since the switching speed of an integrated circuit device is proportional to its power capacity, use of SCD in the manner described herein can lead to an improvement in switching speed of an order of magnitude or more.

Temporary bonding may be used in multiple steps during the processing. Temporary bonding may be used for thinning the IC wafer. Thinning may be performed with an IC wafer with or without bumps. Temporary bonding may be used with an IC wafer with or without bumps. Temporary bonding may be used for thinning the diamond dies (e.g. SCD) or diamond wafers (e.g. SCD). The diamond dies (e.g. SCD) may be placed onto the temporary carrier prior to thinning by a pick and place machine. Temporary bonding may be used to place the diamond dies onto a temporary carrier for bonding to the IC wafer or IC dies. The temporary carrier may be made of glass, silicon, quartz, or silicon carbide. The temporary carrier may match in CTE with the bonded wafer or dies. The temporary carrier may have through holes, e.g. to aid in chemical or solvent debonding. The temporary carrier may be optically transparent, e.g. to aid in optical debonding. The temporary carrier may support electrostatic bonding and debonding. The temporary carrier may contain a buried layer or surface layer that supports optical debonding. The temporary adhesive may be organic. The temporary adhesive may cross-link or be a thermoplastic. The temporary adhesive may contain one coating, or more than one coating. One of these coatings may absorb light, e.g. laser, UV, or pulsed light, which aids in debonding. The temporary carrier may have alignment marks. The temporary carrier may be bonded by a permanent bonding method, e.g. SAB, ADB, PAB, or TCB. The temporary bonding may be accomplished by a mobile electrostatic carrier. The final removal of the temporary carrier may be based on (visible or IR) laser debonding, UV debonding, thermal (slide) debonding, chemical debonding, (thermo-)mechanical debonding, (thermal) solvent debonding, electrostatic debonding, or abrasive and/or chemical removal of the temporary carrier.

The above works for all types of semiconductors including Silicon (Si), Gallium Nitride (GaN) Gallium Arsenide (GaAs), Silicon Carbide, Indium Phosphide (InP), Gallium Oxide (Ga₂O₃), or Aluminum Nitride (AlN) alloys. For GaN chips in power electronics and wireless communication (RF), one could use the exact same processing sequence. For example, starting with a GaN-on-Si device, most of the Silicon underlying the GaN may be removed leaving a layer of Silicon about 5-10 μm thick. Diamond may then be bonded to the Silicon underlying the GaN. Even more preferred, all silicon is removed, followed by removal of the buffer layers and part of the GaN, followed by bonding to diamond. Some bonding techniques, such as surface activated bonding (SAB), plasma assisted bonding (PAB), and atomic diffusion bonding (ADB) allow for direct bonding of GaN to SCD. The resulting device could exhibit a substantial improvement in higher power density as well as a boosted voltage level, allowing GaN to play in the main markets of electric car traction inverters in addition to consumer electronics.

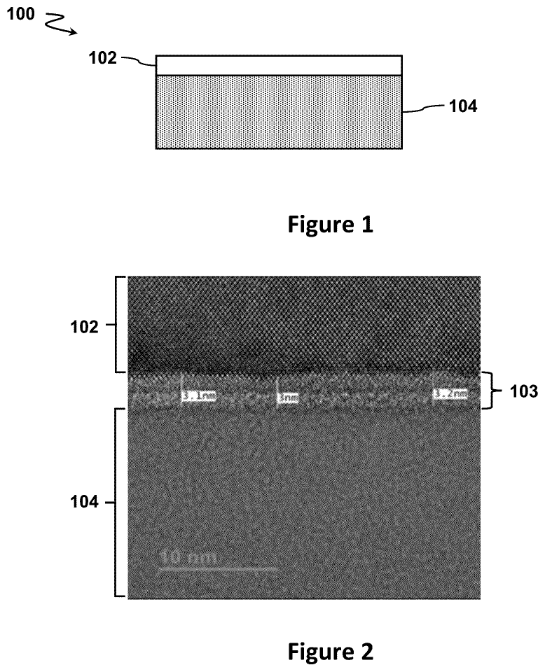

FIG. 1 illustrates an example of a composition of matter 100 according to an aspect of the present disclosure. The composition 100 generally includes semiconductor substrate 102 with one or more layers of diamond 104 disposed on a major surface of the substrate. The one or more diamond layers may be disposed on the semiconductor substrate such that there are not more than two interfaces between a layer of diamond and the surface of the semiconductor substrate to which it is bonded, and an interfacial region between the diamond layer and the surface of the semiconductor substrate is 25 nanometers or less in thickness. By way of example, the semiconductor substrate may be a Silicon substrate, a Silicon-Germanium substrate, a Gallium Arsenide substrate, an Aluminum Nitride substrate, a Silicon Carbide substrate, a Gallium Nitride substrate, a Gallium Nitride on Silicon substrate, a Gallium Nitride on SiC substrate, a GaN Nitride on QST substrate, a GaN Nitride on sapphire substrate, an Indium Phosphide substrate, a Gallium Oxide substrate, or an Aluminum Nitride alloys substrate. The semiconductor substrate may be, e.g., 100 microns or less in thickness, e.g., 50 microns or less, 25 microns or less, 5-10 microns thick, less than 5 microns thick or even less than 1 micron thick, and the diamond layer or layers 104 may be 100-2,000 microns thick, e.g., about 800 microns thick or less, 500 microns thick or less, 300 microns thick or less, or even 100 microns thick or less and yet not thinner than 10 nanometers. The semiconductor substrate 102 and diamond layers 104 may be of any suitable shape and lateral dimensions. By way of example the substrate and/or diamond layers may be characterized by a lateral dimension between 4 mm and 300 mm. In some implementations, the diamond layer(s) may be as thin as 100 nm thick, yet not thinner than 10 nanometers. By way of example, the one or more layers of diamond 104 may include an SCD substrate directly bonded to the semiconductor substrate. Alternatively, the diamond layer 104 may be a film of polycrystalline, nanocrystalline or single crystal diamond that has been deposited by a suitable thin film deposition process. By way of example, and not by way of limitation, diamond may be deposited by chemical vapor deposition (CVD). In a CVD process the semiconductor is seeded, e.g., with AlNₓ, SiNₓ, SiOxNy, SiCN, cBN, or Ir may be deposited on the surface of the semiconductor substrate 102, potentially these materials are covered with diamond nanoparticles, and placed in a chamber along with a carbon-containing gas, such as methane. The chamber is then heated, e.g., to 700-1200° C. and energized, e.g., with microwave energy, to form a plasma cloud. Alternatively, the semiconductor surface is heated to 400° C. and energized, e.g., with microwave energy, to form a plasma cloud. Carbon precipitates out of a plasma cloud and deposits onto the seed surface.

In some implementations in which the diamond layer 104 is an SCD substrate, the substrate may be thinned to a desired thickness, e.g., by lapping, grinding or dry etching prior to bonding. The bonding surface of the SCD may be smoothed, e.g., by chemical mechanical planarization (CMP), prior to bonding. In some alternative implementations, very thin layers of SCD, e.g., as thin as 100 nm thick, may be formed from a thicker diamond material by a “Smart Cut” process. Such a process may involve blanket implanting ions into an SCD ingot to a depth corresponding to the desired thickness of the diamond layer 104. The ion species and implantation energy are chosen to generate a damage layer in the ingot at a desired depth. The surface of the diamond ingot may then be bonded to a carrier and a thin SCD substrate may be split from the ingot at the damage layer. The newly exposed surface of the damage layer may be polished, e.g. by CMP. Alternatively, in some implementations the SCD substrate may be thick, for example greater than 500 microns thick, which may be more expensive to create but with a bigger benefit to the product performance.

Semiconductor substrates of the desired thickness may be obtained by attaching a semiconductor substrate of conventional thickness (e.g., 775 microns) to a temporary carrier, e.g. after creating devices and circuits, and removing semiconductor material that is mainly structural by a thinning process such as backside grinding. In alternative implementations, an etch stop layer (for example and without limitation Si—Ge) is deposited onto a semiconductor substrate, followed by epitaxy of the semiconductor. Devices and circuits are then created in the semiconductor material, followed by attaching the semiconductor substrate to a temporary carrier on the circuit side. The subsequent thinning is aided by the etch stop layer. In yet other alternative implementations, the semiconductor substrate may be produced by a process wherein a (buried) damage layer is produced inside a semiconductor substrate at a desired depth. Subsequently, devices and circuits are created on the semiconductor substrate closest to the damage layer, followed by bonding the circuit side of the substrate to a temporary carrier. Subsequently, the thin device structure is cleaved at the depth of the damage layer from the original semiconductor substrate. A surface finishing step to smoothen the freshly created surface might be applied. Finally, diamonds are bonded to the backside of these device structures. The damage layer might be created by ion implantation followed by cleavage similar to the Smart Cut process. The damage layer may be created by depositing an IR absorbing layer on top of the semiconductor wafer, followed by epitaxial semiconductor deposition to create a buried IR absorbing layer. The IR absorbing layer may be based on, for example and without limitation Germanium. The IR absorbing layer may be a doped semiconductor (e.g. doped silicon), e.g. created by ion implantation into the semiconductor substrate at the desired depth. The cleavage may be based on IR laser irradiation. The cleaving may be thermal, mechanical, thermo-mechanical, chemical, or optical, e.g. by laser cleaving. In one example implementation, a laser through the opposite side of the devices and circuits may be used to cleave the semiconductor wafer with a process similar to KABRA (laser focused on desired depth), optionally with the use of an IR absorbing layer. A similar sequence may be used where the device and circuit manufacturing steps are moved to the end, so after the diamond bonding process. In yet other alternative implementations, the semiconductor material is grown by remote hetero-epitaxy, e.g. with the use of 2D materials, like graphene or BN, on a growth substrate. Subsequently, devices and circuits are created on the semiconductor material, followed by bonding the circuit side to a temporary carrier. Subsequently, the thin device structure is removed from the 2D graphene and the growth substrate. A surface finishing step to smoothen the freshly created surface might be applied. Finally, diamonds are bonded to the backside of these device structures. A similar sequence can be used where the device and circuit manufacturing steps are moved to the end, so after the diamond bonding process. Instead of temporary carriers with temporary adhesives, mobile electrostatic carriers might be used. Alternatively, temporary carriers may be bonded by, for example and without limitation, PAB, or SAB, and later removed. Wafers of SCD are commercially available from Diamond Foundry Inc. of South San Francisco, California. Although wafers of SCD are commercially available, they are expensive and time consuming to manufacture. However, the cost and time may be reduced by using thin SCD wafers, e.g., less than 300 microns thick, preferably less than 100 microns thick. Alternatively, in some implementations, the SCD substrate may be thick, for example greater than 500 microns thick, which may be more expensive to create than thin diamond substrates but may enhance product performance.

In some implementations the semiconductor substrate may be formed directly on the diamond layer 104 by epitaxy. However, epitaxy typically requires forming buffer layers between the semiconductor substrate 102 and diamond layer 104 to accommodate for mismatch in coefficient of thermal expansion (CTE) and lattice mismatch. Such buffer layers may affect thermal performance by introducing additional thermal barrier resistance.

As depicted in FIG. 2, the direct bonding between a silicon semiconductor substrate 202 and diamond layer 204 in the form of an SCD substrate is characterized by a relatively thin interfacial region 203 where atoms at the respective surfaces of the semiconductor substrate and diamond directly covalently bond to each other. In the example depicted in FIG. 2, the semiconductor substrate 202 is made of single crystal silicon and the diamond layer 204 is made of single crystal diamond (SCD). In the particular example illustrated, the interfacial region 203 is about 3 nanometers (3×10⁻⁹ meters) thick, which corresponds to roughly 10 atomic layers of diamond and between 10 and 30 atomic layers of single crystal silicon. By contrast, when diamond is bonded using silver sintering paste, the sintering paste has a thickness of several tens of microns prior to sintering and is at least several microns thick, more commonly tens of microns, after sintering.

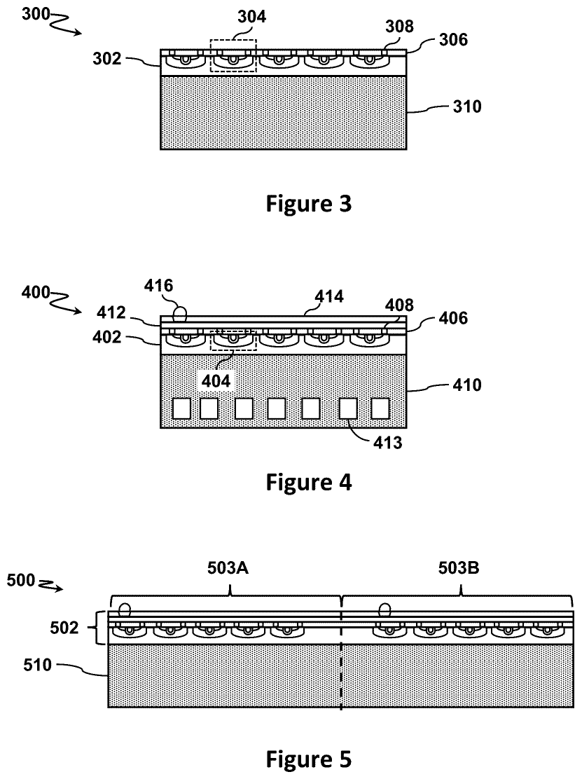

There are a number of different configurations in which semiconductor devices may be fabricated according to aspects of the present disclosure. For example, as shown in FIG. 3, a semiconductor device 300 may include a semiconductor die 302 with integrated circuit (IC) devices 304 (e.g., transistors, diodes, light-emitting diodes, capacitors, resistors, and inductors), formed thereon along with a passivation layer 306 and vertical interconnects 308. The die 302 may be thinned to a thickness of 10 μm or less, e.g., 5-10 μm, 1-5 μm or 0.5-1 μm after the devices 304, an insulating layer 306, and interconnects 308 have been formed and then direct bonded to a SCD substrate 310. The SCD material may be of approximately the same lateral dimensions as the die 302 and may be 2000 μm or less, 800 μm or less, 300 μm or less, or 100 μm or less in thickness and yet not thinner than 10 nanometers. In some implementations, the die 302 may be formed with one or more other dies on a wafer, which may be attached to a carrier and thinned prior to dicing into individual dies. The individual dies may be attached to correspondingly sized diamond dies. In an alternative implementation shown in FIG. 4 an integrated circuit 400 may have a bumped semiconductor device die 402 direct bonded to a diamond substrate 410, e.g., an SCD substrate. In this implementation, the die 402 has been fabricated with IC devices 404, an insulating layer 406, vertical interconnects 408, lateral conductive regions 412, a passivation layer 414 and external conductive contacts 416, e.g., solder bumps or copper pillars. The insulating layer 406, vertical interconnects 408, lateral conductive regions 412, a passivation layer 414 and external conductive contacts 416 may be collectively referred to herein as the chip interconnect or interconnect (IC). The actual number of layers in the chip interconnect may be significantly higher, e.g. 4-8 layers, or 10-15 layers, or 15+ layers, where each layer may contain one or more vertical interconnects and one or more lateral interconnects (lateral conductive regions). The external conductive contacts 416 may be pads (for hybrid bonding), bumps, or pillars. The die 402 and SCD material 410 may be thinned as discussed above with respect to FIG. 3. By way of example, the die 402 may be of any suitable type of IC device dies, such as logic dies (or complementary metal-oxide semiconductor (CMOS) dies) or artificial intelligence (AI) dies or compute dies, or network dies, or memory dies, silicon-based device dies, photonics device dies, power device dies, power amplifier dies, surface acoustic wave (SAW) filter dies, laser dies, display dies, photonics dies, or light detection and ranging (LIDAR) dies. Furthermore, the die 402 may include two or more types of devices, e.g., both logic devices and memory devices. The die 402 may have a number of different configurations for delivering signal and power including, but not limited to no backside power delivery, backside power delivery without memory on top of logic, backside power delivery with memory on top of logic.

In some implementations, the diamond substrate 410 may include one or more channels 413 to accommodate transport of a cooling fluid. In such implementations, the diamond substrate may be thicker than 500 μm. In alternative implementations, the diamond surface facing away from the IC device die 402 may include surface features to improve jet, spray, or impingement cooling of the diamond surface. The surface features may include by way of example and not by way of limitation channels, fins, or textured surfaces, e.g. to optimize fluid flow.

According to aspects of the present disclosure, the SCD may be bonded to a thinned IC prior to dicing wafer-to-wafer (W2 W). For example, as shown in FIG. 5, multiple bumped IC dies 503A, 503B may be fabricated on a semiconductor wafer 502 that is thinned prior to bonding to a SCD substrate 510. The wafer 502 and SCD material 510 may be thinned as discussed above. The individual IC chips 503A, 503B may be diced after bonding, as indicated by the vertical dashed line in FIG. 5.

Dicing of the semiconductor wafer and SCD may be performed anywhere along the process flow. For example, dicing of the semiconductor wafer may be performed prior to complete thinning of the semiconductor wafer, yet before bonding to SCD. In another example, dicing of the semiconductor wafer may be performed after bonding the SCD to the thinned semiconductor wafer. Dicing may be performed by for example and without limitation laser (ablative, or filamentation), water-guided jet laser, blade, plasma, water jet, or any combination thereof. In some implementations the dicing may be performed using stealth dicing techniques.

According to aspects of the present disclosure, 300 mm (or smaller) SCD wafers and semiconductor wafers may be provided to foundries. The semiconductor wafer is processed by the foundry to add all necessary active semiconductor IC devices and IC interconnects. The semiconductor IC wafer may then be thinned (e.g., by backside grinding, or “film transfer”, e.g. SOITEC's SmartCut, more generically called HCut, or EVG's nanocleave, or GaN transfer by 2D materials e.g. graphene, or laser debonding) and bonded to the SCD wafer by SAB, ADB, PAB, TCB, TLPB, solder/eutectic bonding, or organic (polymer) bonding.

For some IC wafer sizes, e.g., 300 mm or 450 mm, suitably sized SCD wafers might not be available or might be prohibitively expensive. In such cases, multiple SCD dies may be bonded to an IC wafer in a collective-diamonds-to-wafer (CD2 W) fashion and the resulting composite wafer may be diced after bonding. The SCD dies may be positioned by pick-and-place onto a temporary carrier prior to bonding. In another implementation, the SCD dies are bonded to the IC wafer by SD2 W. In yet another implementation, the SCD dies are bonded by CD2CD with the IC wafer diced to the IC dies prior to bonding. In yet another implementation, the SCD die may be bonded to the IC die by D2D.

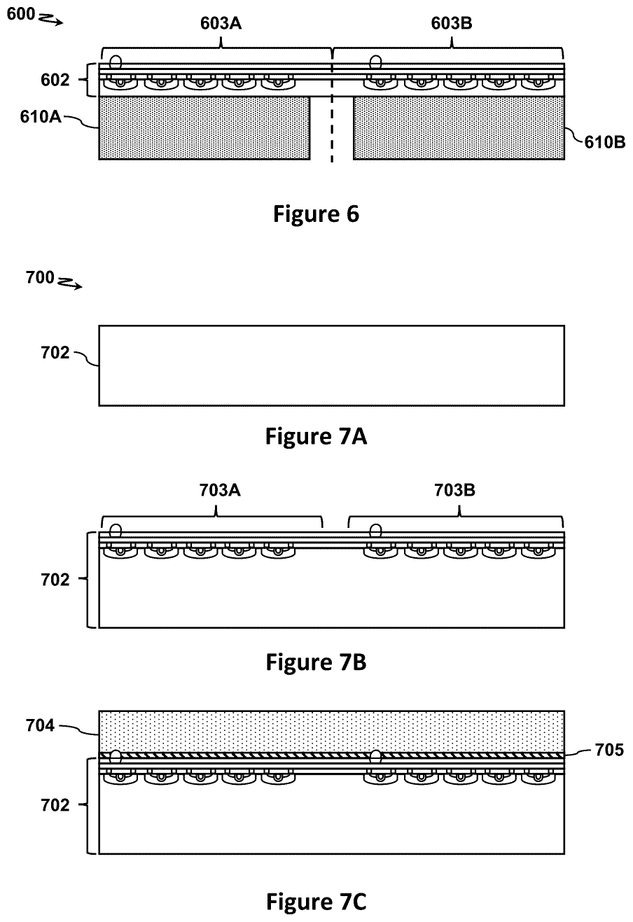

By way of example, as shown in FIG. 6, multiple SCD substrates 610A, 610B may be bonded to a fabricated wafer 602 after thinning but prior to dicing at locations corresponding to individual bumped IC device dies 603A, 603B. The wafer 602 and SCD materials 610A, 610B may be thinned as discussed above. The resulting structure may then be diced as indicated by the vertical dashed line in FIG. 6.

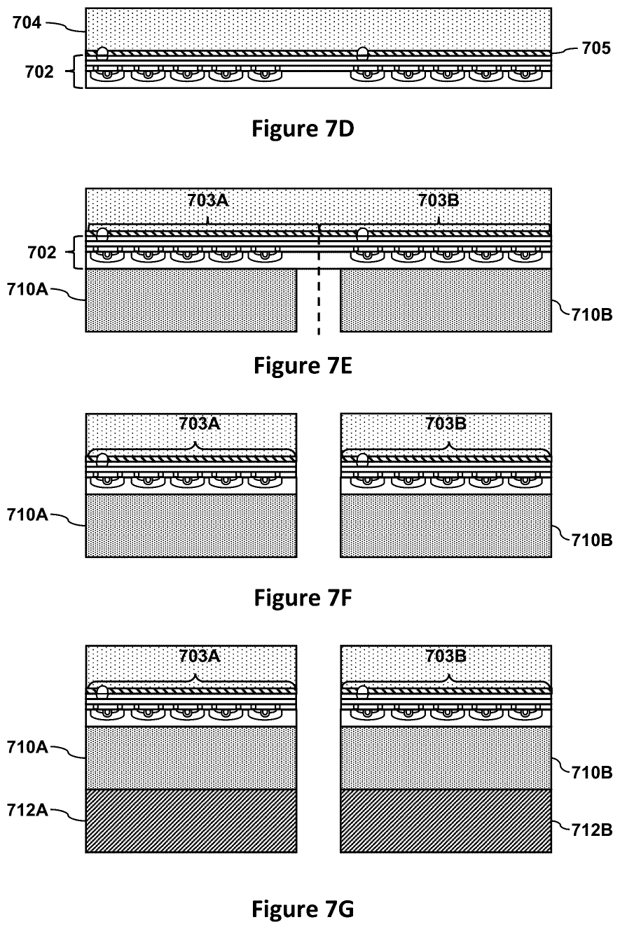

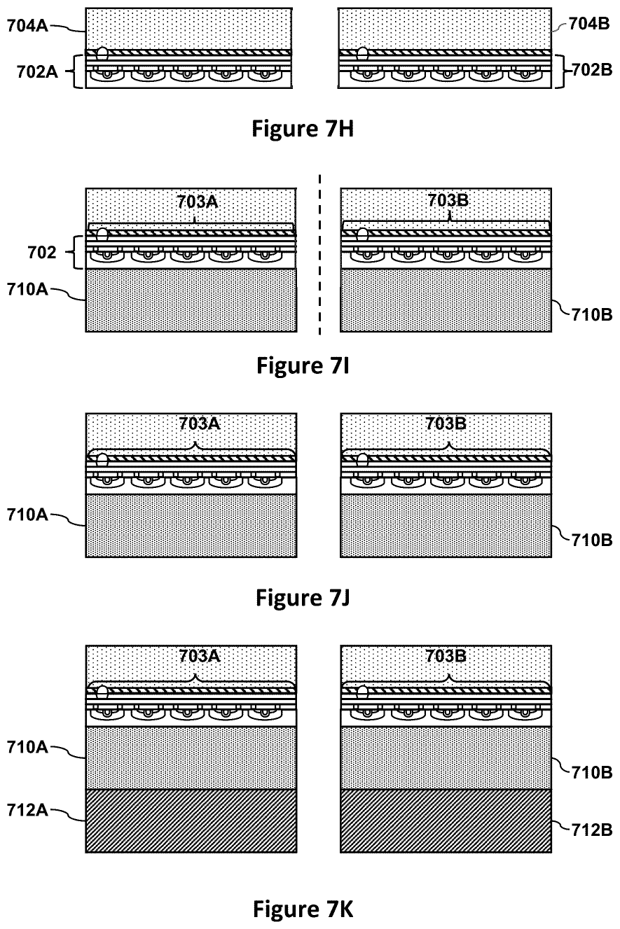

A composition of matter of the type depicted in FIG. 6 may be fabricated as shown in FIGS. 7A-7F. Specifically, the fabrication may start, as shown in FIG. 7A, with a semiconductor substrate 702. By way of example, the semiconductor wafer may be a single crystal silicon wafer of a standard size, e.g., diameter of 100 mm, 150 mm, 200 mm, 300 mm, or 450 mm. The wafer thickness may depend on the wafer size. For example, a 300 mm wafer may be 775 μm thick and a 200 mm wafer may be 725 μm thick. Next, as shown in FIG. 7B multiple IC device dies 703A, 703B may be fabricated on the semiconductor substrate 702 in a conventional manner. The conventional manner may include typical front-end of line (FEOL), middle-end of line (MEOL), and back-end of line (BEOL) fabrication steps. Each integrated circuit device die 703A, 703B may include transistors, lateral and vertical copper interconnects embedded in a dielectric or insulating material, e.g. vertical conductive vias, lateral conductive lines or wires, pads, pillars, and bumps. In addition, external connections may be made by solder balls.

A carrier 704 is then attached to the front side of the fabricated wafer 702, as shown in FIG. 7C. The carrier 704 may be made of glass, quartz, silicon, or silicon carbide (SiC), and coated with a high shear bond strength adhesive 705, e.g., of a type commonly used for backside grinding. In addition to the adhesive, the carrier might be coated by an optical absorber, e.g. for laser or optical pulse (e.g. PulseForge) debond. This results in a stack of two layers between carrier and wafer: absorber layer and adhesive. Suitable adhesives are commercially available, e.g., from 3M, Brewer Science, Dow, Hitachi Dupont, or DuPont. Suitable carriers meet tight dimensional tolerances, and, when possible, are matched based on coefficient of thermal expansion. Next the backside of the wafer 702 may be thinned to a thickness of 10 μm or less, as shown in FIG. 7D while bonded to the carrier 704. In some implementations, the wafer 702 may be thinned to less than 5 μm. The active part of the semiconductor is probably less than 2 μm thick, perhaps less than 1 μm, perhaps as little as 50 nm, or even below 25 nm, depending on the thickness of semiconductor material required to avoid detrimentally affecting device performance. The thickness of the active portion depends on the size of the transistors in the IC device dies 703. Generally, as transistors get smaller laterally, they get thinner. The final thickness of the wafer after thinning may also depend on total thickness variation (TTV) resulting from the thinning process and dicing interplay.

After thinning and smoothening the wafer 702, SCD substrates 710A, 710B are directly bonded to the backside of the wafer at locations corresponding to the IC device dies 703A, 703B, as depicted in FIG. 7E. A pick-and-place tool may be used to position the SCD substrates, e.g., onto a temporary carrier (not shown in FIG. 7) when using a wafer bonder, e.g. for CD2 W. A pick-and-place tool may be used to position the SCD substrates directly onto the wafer 702, e.g. for SD2 W. Each SCD material 710A, 701B may be of approximately the same dimensions as the corresponding IC dies 703A, 703B. The SCD materials may be relatively thin, though generally thicker than the IC dies. For example, the SCD materials 710A, 710B may be 2000 μm or less, 800 μm or less, 500 μm or less, 300 μm or less in thickness, perhaps 100 μm or less and yet not thinner than 10 nanometers. The semiconductor substrate may then be diced through the carrier 704 to separate the individual IC device dies 703A, 703B, as shown in FIG. 7F. Alternatively, the temporary carrier 704 in contact with the wafer 702 is first removed, followed by dicing through 702, followed by removal of the temporary carrier (not shown in FIG. 7) in contact with the SCD dies, e.g. for the CD2 W process flow.

In an alternative implementation composition of matter of the type depicted in FIG. 6 may be fabricated in a collective-die-to-collective-die (CD2CD) configuration as shown in FIGS. 7H-7K. As shown in FIG. 7H, two or more separate integrated circuit device dies 703A, 703B may be fabricated on corresponding semiconductor wafers 702A, 702B, with a corresponding carrier 704A, 704B attached to the front side of each die. By way of example, the separate device dies 703A, 703B may be fabricated from a single semiconductor wafer and attached to a single carrier and carriers may be attached to the front side of the resulting structure, e.g., as shown in FIGS. 7A-7D and discussed above. Alternatively, the device dies 703A, 703B may be fabricated separately and attached to separate carriers 704A, 704B.

After the carriers 704A, 704B are attached to the front sides of the device die 703A, 703B, the back sides of the device die may be thinned and smoothened. The thinning and smoothening process most typically is performed prior to dicing the wafer into dies. Subsequently, these thinned IC device dies on diced carriers may be placed onto another temporary carrier (not shown in FIG. 7) for CD2CD wafer bonding. SCD materials 710A, 710B may then be direct-bonded to the back sides of the device dies, as shown in FIG. 7I. Each SCD material 710A, 701B may be of approximately the same dimensions as the corresponding IC dies 703A, 703B. A pick-and-place tool may be used to position the SCD substrates, e.g., onto a temporary carrier (not shown in FIG. 7) when using a wafer bonder, as discussed above for CD2 W, yet now for CD2CD, or alternatively directly onto the IC dies, e.g. for D2D. Subsequent processing, depicted in FIGS. 7J-7K, may proceed as discussed above with respect to FIGS. 7F-7G.

In an alternative implementation instead of direct bonding SCD substrates to the backside of the wafer at locations corresponding to the IC device dies 703A, 703B, a seed layer of AlNₓ, SiNₓ, SiOxNy, SiCN, cBN, or Ir may be deposited on the surface of the IC device dies 703A, 703B, optionally a thin barrier layer may be deposited prior to deposition of the seed layer placing it underneath the seed layer. The barrier layer may be comprised of for example and without limitation TiN, STO, or YSZ. A diamond film (which may be for example and without limitation nanocrystalline, micro-crystalline, or polycrystalline) may then be grown over the seed layer to form a diamond heat spreader. Prior to growth, the seed layer may be exposed to diamond nanopowder. These diamond layers may be formed at low-temperature, while still having high-thermal conductivity diamond film growth. The thickness range of this diamond film may be between 50 microns and 300 microns.

One advantage of bonding die-sized SCD substrate to individual device die on a wafer is that it can enhance the effective yield of useful devices after singulation. For small node devices, e.g., as used for artificial intelligence (AI), the yield of known good die (KGD) can vary a lot on 300 mm wafers and can be less than 50%. However, the device die may be tested in a conventional manner prior to bonding of the SCD dies and singulation of the semiconductor wafer. Therefore, according to aspects of the present disclosure, a wafer map of known good dies may be obtained and SCD may only be bonded to known good dies. This saves cost as less SCD is wasted by being bonded to bad device dies.

According to additional aspects of the present disclosure, the composite device dies with the semiconductor IC and integrated SCD thermal management dies may be further integrated with a cooling system for the IC. For example, as shown in FIG. 7G or FIG. 7K, heat sinks 712A, 712B may be attached to the back sides of the SCD thermal management dies 710A, 710B, respectively. By way of example, the heat sinks may be made of a relatively thick substrate made of a highly thermally conductive material, such as copper. The thermal conductivity of copper is about 401 W/m-K at 25° C., which is less than that of diamond but more than that of silicon. As used herein, “relatively thick” refers to thickness greater than or equal to that of the SCD. The heat sink can be designed for various cooling scenarios, e.g., air cooling, liquid cooling, cold plate cooling, immersion cooling, one-phase cooling, two-phase cooling, microchannel cooling, spray cooling, jet cooling, or impingement cooling. The heat sinks may be made out of copper, aluminum, silicon, graphite, silicon carbide, or 3D printed from polymers. The heat sinks may be a boiling enhancement coating for immersion cooling. The heat sinks may be attached to the full surface of the diamond heat spreader, or only to the perimeter, e.g. in case of jet (impingement) cooling where the cooling fluid directly contacts the diamond surface.

According to aspects of the present disclosure, the direct bonding process results in a thermal barrier resistance (TBR) that is as low as possible. In general, it is desirable that there be little to no material between the SCD material and the semiconductor material and only one or two interfaces once bonding is complete. According to aspects of the present disclosure, some direct bonding techniques may involve an interfacial layer of 25 nm thickness or less between the SCD material and the semiconductor material. Examples of bonding techniques include Surface Activated Bonding (SAB), modified SAB, and Atomic Diffusion Bonding (ADB). However, Plasma Assisted Bonding (PAB), Thermo-Compression Bonding (TCB), Transient Liquid Phase Bonding (TLPB), solder/eutectic bonding, and polymer bonding can be made to work for a low thermal barrier resistance as well.

According to aspects of the present disclosure SAB and ADB are attractive techniques for direct bonding of semiconductor substrates to SCD wafers or dies because they have better thermal performance since no or minimal additional materials are added. They also have fewer process steps and may be done at room temperature. For both SAB and ADB, the bonding surfaces need to be clean from organics and particles, contamination free, typically oxide free, flat (e.g., angstrom level) and smooth to achieve a high bond strength and low thermal resistance. To achieve the desired bond strength, both SAB and ADB are done in ultra-high vacuum (UHV) environments in which the ambient pressure is about 10⁻⁸ mbar or less. By way of example, and not by way of limitation, SAB equipment is made by EV Group of Florian am Inn, Austria, Ayumi Industry Co. LTD of Himeji City, Japan, Bondtech Co. Ltd of Kyoto, Japan, Nidec Corporation of Kyoto, Japan. ADB equipment is commercially available, e.g., from Canon Anelva Corporation of Kanagawa, Japan.

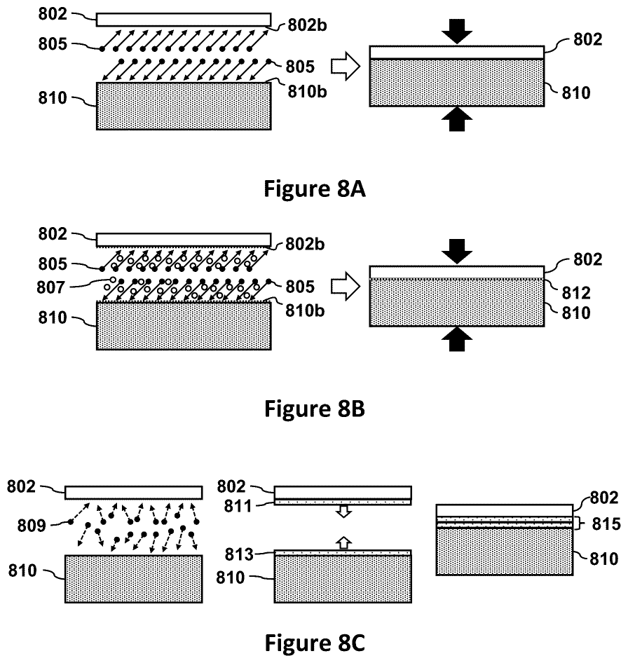

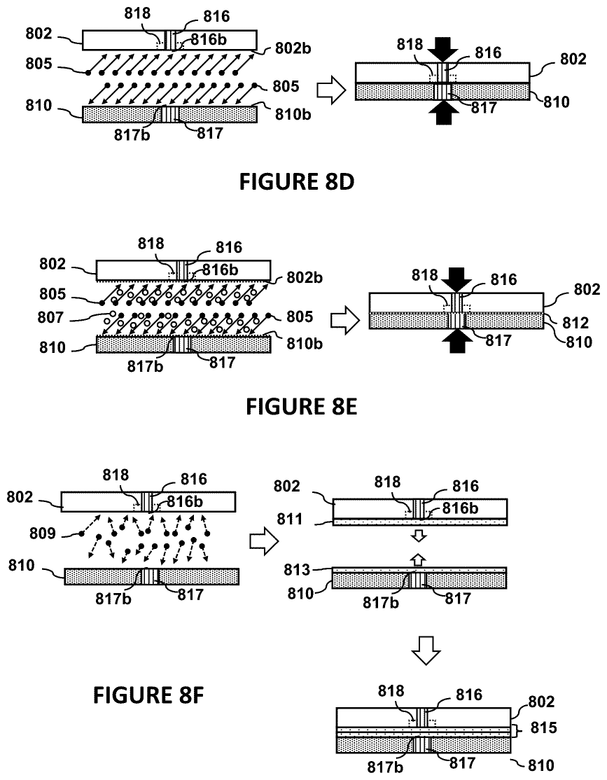

FIG. 8A schematically illustrates the SAB process. Generally, the respective bonding surfaces 802b, 810b of a semiconductor substrate 802 and SCD substrate 810 are cleaned of contaminants, e.g., organics, metals, and particles.

The bonding surfaces are treated with beams of atoms or ions 805 in an ultra-high-vacuum (UHV) environment to remove remaining contaminants (e.g., organics, metals, and oxides) and create reactive dangling bonds and typically amorphize a few nanometers of each bonding surface (1-5 nm). Typically, Argon atoms or ions are used. Amorphizing the bonding surfaces 802b, 810b avoids potential issues with lattice mismatch. The treated surfaces are then subject to bonding pressure (force) under UHV, as indicated by the black arrows. The UHV environment allows for a few minutes to bring surfaces into contact and form strong (e.g. covalent) bonds. The bonding may be done at relatively low temperature, e.g., in the range of room temperature (about 25° C.). The resulting bonds are free of a significant thickness of intermediate material. As a result of the amorphization, there may be an interface region of amorphous material between the bulk crystalline semiconductor and the bulk crystalline SCD with an interface between the two amorphous materials. The amorphous material region is, however, quite thin, e.g., 2-10 nm in thickness, which is quite insignificant compared to a semiconductor wafer 1-10 μm thick or a thermal interface material (TIM) of 100 μm. The resulting bonds are also quite strong. For example, in the case of a silicon semiconductor substrate bonded to SCD, the bonds have a pull strength of 10's MPa, e.g. 80 MPa. This is advantageous as stronger bonding generally improves thermal performance, and strong bonds last longer.

For bonding Silicon (Si) to SCD by SAB additional films are typically not required. However, to bond some semiconductor substrates by SAB, such as GaN-on-SCD, additional films may be needed (e.g. Silicon (Si) or Aluminum Nitride (AlN) or Silicon Nitride (SiNₓ) or Silicon Carbonitride (SiCN)) for bond strength. To bond such semiconductor materials, the SAB process may be modified by incorporating atoms or ions of bonding material into the ionic or atomic beams used for surface activation of both bonding surfaces 802b, 810b. FIG. 8B schematically illustrates an example of a modified SAB process. As with conventional SAB, the respective bonding surfaces of a semiconductor substrate 802 and SCD substrate 810 are cleaned of contaminants. As with conventional SAB, the bonding surfaces are treated with beams of atoms or ions 805 in a UHV environment. However, atoms or ions 807 of bonding material are included with the treatment beams 805 and incorporated into the bonding surfaces, as indicated by the dotted lines. Typically, the bonding atoms or ions may be the same as those of the bulk semiconductor substrate 802. For example, silicon atoms may be used when bonding a silicon substrate to an SCD substrate. The bonding surfaces 802b, 810b are then brought into contact under UHV and subjected to bonding pressure (force) and/or temperature. The bonding atoms incorporated into the bonding surfaces assist in forming bonds between the amorphous regions at the bonding surfaces. The amorphous material region 812 can still be quite thin, however, e.g., 2-10 nm in thickness. Another way of incorporating thin films for SAB bonding is by thin film deposition prior to surface activation, e.g. by atomic layer deposition, sputtering, pulsed laser deposition, MOCVD, MBE, CVD, or electron beam deposition. One or both surfaces might be deposited with a thin film prior to SAB. Furthermore, the semiconductor substrate and SCD substrate might be treated (surface activation) prior to thin film deposition in addition to surface activation of the film surfaces prior to SAB bonding.

FIG. 8C schematically depicts an ADB process. Generally, the respective bonding surfaces 802b, 810b of a semiconductor substrate 802 and SCD substrate 810 are cleaned of contaminants outside of an ADB tool. Next, UHV thin films 811, 813 (e.g., 1-5 nm) of metal (e.g., Ti) or semiconductor (e.g., Si or AlN) or oxide is formed on the bonding surfaces 802b, 810b, e.g., by sputtering of atoms, ions, neutral species, or clustered species 809. The thin films 811, 813 may be amorphous or crystalline films. Because the films 811, 813 are freshly created in UHV they bond together very effectively by bringing the surfaces into contact with each other and subjecting them to little or no pressure (force) and minimal/no heating. The resulting structure has two interfaces, one between the semiconductor substrate 802 and an interfacial bonding layer 815 and another between the interfacial bonding layer 815 and the SCD substrate 810. However, the interfacial layer can be quite thin, e.g., 25 nm or less in thickness.

Plasma Assisted Bonding (PAB, sometimes called plasma-activated bonding, plasma-activation bonding, fusion bonding, dielectric bonding, or hydrophilic bonding) is typically performed by a low-force (e.g. less than 1 MPa), low-temperature (e.g. room temperature), atmospheric or (low) vacuum bonding of two hydrophilic and reactive surfaces, optionally with nanopores, followed by a post-bond anneal to strengthen the bond. PAB is optionally (albeit uncommonly) followed by anodic bonding to further strengthen the bonds. PAB refers to the bonding of dielectrics. Some examples of thin films that may be used for bonding are SiO₂ or SiCN thin films. For these thin films, annealing (e.g. at 200° C. to 350° C.) may be required after bonding. A process flow may start with CVD of the bonding dielectric (e.g. SiCN, SiO₂, or SiNₓ), optionally densification of the CVD film by annealing, optionally planarization of bonding dielectric (e.g. by CMP), cleaning (e.g. megasonic DI rinse), plasma activation, optionally cleaning (e.g. megasonic DI spin rinse) or hydration, alignment, bonding at room temperature, and annealing to strengthen the (dielectric) bond. One consideration is control of the amount of water inside the film and on the film's surface to ensure sufficient bond strength prior to annealing, and minimal voids after annealing. The presence of water inside the film and on the film's, surface is controlled by e.g. film density, film composition, plasma activation, exposure to water, and optionally removal of excess water, e.g. by anneal or vacuum. All processing is best performed in a clean room with controlled temperature and humidity. Similarly, part or all of the processing is best performed in a controlled environment between steps (e.g. in an integrated tool) with controlled process time between steps. Typical (PECVD) film thickness (e.g. SiCN, SiO₂, or SiNₓ) is well over 100 nanometers, often with bondline thickness of 100's nanometers for films with a thermal conductivity of only ˜1 W/m-K. It is beneficial for thermal resistance, however, to reduce film thickness and/or increase the thermal conductivity of the films and add minimal interfaces, e.g. minimal number of films (e.g. no or limited number of adhesion and barrier layers).

An example PAB process flow starts with deposition of a thin film on one or both of the bonding surfaces after surface cleaning. In some implementations the thin film may be formed over an adhesion layer (for example and without limitation, Titanium, Chromium, Titanium-Carbide, Chromium Carbide) and/or a diffusion barrier layer (for example and without limitation Nickel, Platinum, Nickel-Vanadium, TiN, or TaN). In some implementations the surface might undergo a surface treatment to improve adhesion to the subsequent film, e.g. a plasma based activation or functionalization step. In some implementations the semiconductor surface might undergo a conversion step, e.g. thermal oxidation to form a thermal silicon oxide. Optionally, deposition may be followed by an anneal step for film densification. Then planarization of the thin film (by for example and without limitation CMP), and cleaning (by for example and without limitation megasonic deionized water (DI) spin rinse). After cleaning the thin film may be subjected to plasma activation (by for example and without limitation high voltage electrical discharge in the presence of high concentrations of Nitrogen, Oxygen, or Argon species, by for example and without limitation process conditions of 200-400V, 50-200 mA, 50-300 mTorr, 50-200 W) to remove contamination and create a reactive surface (activation). Diffusion barriers may be selected from one or a stack of more than one of the following: Ti, Ta, TiC, tantalum carbide, TiN, TaN, Cr, chromium carbide, CrN, W, WN, Ti—W alloys, Ni, Ni—V, silicides (e.g. based on Ni), high entry alloys, platinum group metals (e.g. Pt, Pd), or 2D materials (e.g. graphene).

After activation, the thin films on the bond surfaces are subjected to cleaning, hydration, or hydrophilicity enhancement (e.g., megasonic DI spin rinse). The diamond substrate and semiconductor substrate are then aligned and pressed together at room temperature (e.g. in vacuum or air) to bond the surfaces. Alignment may be performed by any suitable alignment method, for example and without limitation a pick-and-place machine for dies, a dedicated alignment unit for wafer bonders, or by self-alignment of dies using a liquid. Finally, the composition is annealed to strengthen the (dielectric) bond. PAB may create a thin interfacial bonding layer comprised of material of the thin film(s), optionally containing additional elements originating from the plasma activation, (ambient) environment, or water exposure (e.g. oxide).

Dry cleaning, activation, or surface termination may be accomplished by a plasma or a beam source. The plasma may be planar or cylindrical shaped. The beam may be a point source or linear. The plasma or beam source may contain ions, atoms, radicals, electrons, or molecules. The plasma or beam source may be generated by an electric field, gas discharge, radiation, or heating, e.g. radio frequency power, microwaves, alternating or direct current, or UV. Examples are reactive ion etching (RIE), electron cyclotron resonance plasmas, inductively coupled plasmas, capacitively coupled plasmas, neutral loop discharge plasmas, microwave generated radical beams, argon atom or ion beams, nitrogen beam sources, electron enhanced material processing by fine-tuned waves of electrons from low temperature DC plasma, etc. Surface termination may be performed to facilitate further surface functionalization (e.g. chlorine termination to facilitate subsequent generation of a diamond hydrophilic surface, or e.g. nitrogen termination to facilitate subsequent generation of a hydrophilic surface on a dielectric film) or to passivate the surface for a sufficient amount of time prior to bonding, e.g. with atmospheric plasmas, e.g. a helium-based clean and nitrogen termination of a metal surface to temporarily passivate the surface against oxidation prior to metal bonding. Suitable gas species used for dry cleaning, activation, or termination treatments include argon, helium, nitrogen, ammonia, oxygen, water, hydrogen, forming gas, fluorine-based gasses, etc. Dry cleaning, activation, or surface termination may be performed in ultra-high vacuum (e.g. for SAB), low vacuum (e.g. for PAB), or at atmospheric pressure (e.g. for metal oxide removal). Process temperature may be controlled. Dry cleaning, activation, or surface termination may be used for SAB, ADB, PAB, TCB, TLPB, solder/eutectic bonding, or polymer bonding.

The bonding in plasma-assisted bonding (PAB) is typically performed by a low-force (e.g. less than 1 MPa), low-temperature (e.g. room temperature), atmospheric or (low) vacuum bonding of two hydrophilic and reactive surfaces, optionally with nanopores, followed by a post-bond anneal to strengthen the bond. Both surfaces are made of a dielectric, e.g. SiCN, SiO₂, or SiNₓ, typically 100 nanometers or thicker. However, the diamond surface may be made hydrophilic without the need for a (thick) film. The diamond surface may be made hydrophilic by surface treatments, and film depositions. The same holds for the opposite surface (e.g. silicon) for bonding. Most diamond surfaces are hydrophobic (hydrogen terminated). Diamond surfaces may be treated to increase hydrophilicity which is beneficial for low-force, low-temperature bonding (placement), optionally followed by annealing after (PAB) bonding. A hydrophilic diamond surface may contain one (majority) or more (a mixture) of the following: ethers, carbonyls, lactones, carboxylic anhydrides, ketones, or hydroxyl groups. All processing is best performed in a clean room with controlled temperature and humidity. Similarly, part or all of the processing is best performed in a controlled environment between steps (e.g. in an integrated tool) with controlled process time between steps. In an example process the diamond surface may first be cleaned from contaminants (e.g. organics, metals, particles). Subsequently, the diamond surface may be exposed to a mixture of NH₄OH and H₂O₂ in (deionized) water at elevated temperatures (e.g. over 70° C. for 1 to 10 minutes), optionally followed by exposure to a monolayer of water (e.g. in ALD chamber), oxygen gas with controlled humidity, water vapor, air, or (deionized) water (e.g. by spin rinse). Next an anneal around or above 100° C. or a (hot) vacuum treatment may optionally be performed to control the water layer thickness on the surface prior to bonding. In a second example process, a hydrophilic diamond surface may be generated by converting a hydrogen terminated surface to a chlorinated surface by heating to 250-400° C. in the presence of chlorine, followed by the exposure to water at room temperature. Optionally the diamond surface may then be exposed to a monolayer of water (e.g. in ALD chamber), oxygen gas with controlled humidity, water vapor, air, or (deionized) water (e.g. by spin rinse). Next the surface may then optionally be either annealed at around or above 100° C. or subject to a (hot) vacuum treatment to control the water layer thickness on the surface prior to bonding. In a third example, the diamond surface is heated (typically in a range of 300° C. to 500° C.) in the presence of an oxygen source (e.g. O₂), optionally followed by exposure to a monolayer of water (e.g. in ALD chamber), oxygen gas with controlled humidity, water vapor, air, or (deionized) water (e.g. by spin rinse). Next the surface may optionally be either annealed at around or above 100° C. or subject to a (hot) vacuum treatment to control the water layer thickness on the surface prior to bonding. In yet another example, the diamond surface is treated with a plasma containing e.g. nitrogen or argon, optionally followed by exposure to a monolayer of water (e.g. in ALD chamber), oxygen gas with controlled humidity, water vapor, air, or (deionized) water (e.g. by spin rinse), optionally followed by either an anneal at around or above 100° C. or a (hot) vacuum treatment to control the water layer thickness on the surface prior to bonding. In yet another example, the diamond surface receives a UV ozone treatment, optionally followed by exposure to a monolayer of water (e.g. in ALD chamber), oxygen gas with controlled humidity, water vapor, air, or (deionized) water (e.g. by spin rinse), optionally followed by either an anneal at around or above 100° C. or a (hot) vacuum treatment to control the water layer thickness on the surface prior to bonding. In yet another example, the diamond surface is treated with an argon based (fast) atom beam or argon-based ion beam, optionally containing silicon species. Next the surface may optionally be exposed to a monolayer of water (e.g. in ALD chamber), oxygen gas with controlled humidity, water vapor, air, or (deionized) water (e.g. by spin rinse), optionally followed by either an anneal at around or above 100° C. or subject to a (hot) vacuum treatment to control the water layer thickness on the surface prior to bonding. In yet another example, the diamond surface is treated with a nitrogen-based beam, optionally containing silicon species. Next the surface may optionally be exposed to a monolayer of water (e.g. in ALD chamber), oxygen gas with controlled humidity, water vapor, air, or (deionized) water (e.g. by spin rinse), optionally followed by either an anneal at around or above 100° C. or a (hot) vacuum treatment to control the water layer thickness on the surface prior to bonding. Alternatively, a hydrophilic surface may be created on either surface, e.g. the diamond surface, by depositing a thin (e.g. 5 nanometers) hydrophilic film, e.g. by atomic layer deposition (ALD) or chemical vapor deposition (CVD), like films based on alumina, titania, or silica. Oxygen sources like water, ozone, oxygen (plasma enhanced), tetraethoxysilane, and nitrous oxide are commonly used for the oxide deposition, e.g. silicon oxide.

A first PAB example uses alumina or silica or titania or silicon nitride film deposition (e.g. 5 nanometers by ALD) on one or both surfaces, followed by plasma activation. Next one or both surfaces may be exposed to water, followed by coupling both bond surfaces and anneal at between 200° C. and 350° C. A second PAB example uses silicon carbon nitride film deposition (e.g. 10 nanometers by PECVD) on one or both surfaces, followed by plasma activation. Next one or both surfaces may be exposed to water, followed by coupling both bond surfaces and annealing at between 200° C. and 350° C. A third PAB example uses silicon nitride film deposition (e.g. 10 nanometers by PECVD) on one or both surfaces, followed by plasma activation and water exposure. Finally, the bonding surfaces may be placed in contact with each other and annealed at between 200° C. and 350° C. A fourth PAB example uses silicon carbide film deposition (e.g. 10 nanometers by PECVD) on one or both surfaces, followed by plasma activation, and water exposure. Finally, the bonding surfaces are placed on top of each other and annealed at between 200° C. and 350° C. A fifth PAB example uses silicon carbide film deposition (e.g. 10 nanometers by PECVD) on one or both surfaces, followed by plasma activation, and water exposure. The bonding surfaces are coupled and annealed at between 200° C. and 350° C. A sixth PAB example uses aluminum nitride film deposition (e.g. 15 nanometers by PECVD) on one or both surfaces, followed by plasma activation, and water exposure. The bonding surfaces are bonded to each other and annealed at between 200° C. and 350° C. A seventh PAB example uses aluminum nitride or titanium nitride or tantalum nitride film deposition (e.g. 5 nanometers by ALD) on one or both surfaces, followed by plasma activation, and water exposure. The bonding surfaces are coupled to each other and annealed at between 200° C. and 350° C. It should be understood that both film composition and film thickness can vary on each surface prior to bonding. For example, bonding 10 nm silicon carbon nitride to 5 nm silicon oxide. Alternatively, bonding 10 nm silicon oxide to 5 nm silicon nitride. Further example, bonding 5 nm aluminum nitride to 5 nm silicon carbon nitride. In yet another example, bonding 5 nm silicon carbon nitride to 10 nm silicon carbon nitride. In yet another example, bonding 10 nm silicon carbon nitride on IC die to a SCD surface that has been made hydrophilic by functionalization.

Deposition of thin films may be performed by any suitable deposition method for example and without limitation plasma enhanced CVD, thermal CVD, microwave CVD, hot wire CVD, MOCVD, Physical vapor deposition (PVD), electron beam enhanced sputtering, ion beam enhanced sputtering, thermal evaporation, e-beam evaporation, pulsed laser deposition, atomic layer deposition (ALD), plasma-enhanced ALD (PE-ALD), thermal ALD, molecular beam epitaxy (MBE), high-power impulse magnetron sputtering (HIPIMS), etc. Alternatively, deposition may include coating the bonding surfaces with a polymer and creation of polymer-derived ceramics by decomposition/conversion (e.g. anneal, rapid thermal anneal, laser, pulsed light source, ultrasound, microwave, etc.). For example, and without limitation, starting from polysilazane derivatives (e.g. polyborosilazane), polysiloxane derivatives, polysilane derivatives (e.g. polycarbosilane), polysilsesquioxanes, polysilsesquiazanes, polysilylcarbodiimides, etc. These polymers may be deposited by spin coating, spraying, jetting, dip coating, etc. followed by decomposition/conversion. Depending on the decomposition/conversion process conditions the formed ceramic might be a polymer/ceramic composite, amorphous ceramic, or crystalline ceramic. Alternatively, spray pyrolysis or sol-gels may be used to create a ceramic on the bonding surface.

Thin film materials for PAB may be any dielectric or thin film material that can be activated by a plasma (or beam), made hydrophilic, and is optionally able to accommodate or diffuse water. However, to be suitable as a low thermal interface resistance bond material, deposition methods need to allow for thin films, e.g. 10 nanometers thick, and/or the thermal conductivity needs to be higher than the typical ˜1 W/m-K for typical PECVD films like SiO₂. Some example thin film materials include Silicon-Carbon-Nitride and carbon-nitride derivatives such as Boron-Carbon-Nitride, Aluminum-Carbon-Nitride, Germanium-Carbon-Nitride, Titanium-Carbon-Nitride, Zirconium-Carbon-Nitride, Hafnium-Carbon-Nitride, Vanadium-Carbon-Nitride, Niobium-Carbon-Nitride, Tantalum-Carbon-Nitride, Chromium-Carbon-Nitride, Molybdenum-Carbon-Nitride, and Tungsten-Carbon-Nitride. Other examples are Y-Oxygen-Carbon-Nitride-derivatives where Y is selected from the list of suitable atoms consisting of Silicon, Boron, Aluminum, Germanium, Titanium, Zirconium, Hafnium, Vanadium, Niobium, Tantalum, Chromium, Molybdenum, and Tungsten. The thin film may include a carbide derivative such as Y-carbide where Y is selected from the list of suitable atoms consisting of Silicon, Boron, Aluminum, Germanium, Titanium, Zirconium, Hafnium, Vanadium, Niobium, Tantalum, Chromium, Molybdenum, and Tungsten. The thin film may include Nitride containing materials having the formula Y-Nitride where Y is a suitable atom selected from the list consisting of Silicon, Boron, Aluminum, Germanium, Titanium, Zirconium, Hafnium, Vanadium, Niobium, Tantalum, Chromium, Molybdenum, and Tungsten. Other types of thin film that may be suitable include oxide derivatives such as oxides of Silicon, Boron, Aluminum, Germanium, Titanium, Zirconium, Hafnium, Vanadium, Niobium, Tantalum, Chromium, Molybdenum, or Tungsten.

In some implementations the thin film may be an amorphous film of carbon, diamond-like carbon, or tetrahedral amorphous carbon. The thermal conductivity of amorphous carbon or diamond-like carbon films can be tuned from below 0.1 W/m-K to 1000 W/m-K and tetrahedral amorphous carbon can be tuned to have a thermal conductivity around 3.5 W/m-K.

In some implementations the thin film may be an amorphous or nanocrystalline thin film of BeO, e.g. with a thermal conductivity as high as 10-15 W/m-K. In some implementations the thin film may be an amorphous or nanocrystalline thin film of TiN, e.g. with a thermal conductivity of 10 W/m-K, and deposited by ALD, CVD, or PVD. In some implementations the thin film may be an amorphous or nanocrystalline thin film of AITiN, e.g. with a thermal conductivity of 5 W/m-K.

Similarly, other amorphous films may be suitable such as amorphous thin films of silicon oxide (silica), hafnia, alumina, titania, or BeO. In some implementations the suitable amorphous films and/or nanocrystalline films may be elemental films (by way of example and not by way of limitation, a-Si, a-Ge, a-C), alloy films (for example and without limitation, Si—Ge) or multinary dielectric thin films (for example and without limitation Si—Al—N, Si—B—N, Si—Ge—N, Si—Ti—N, Si—Al—C, Si—B—C, Si—Ge—C, Si—Ti—C, Si—Al—C—N, Si—Ge—C—N, Si—B—C—N, Si—Ti—C—N, etc.). In some implementations the suitable amorphous and/or nanocrystalline thin films may be nitrides (e.g. SiNₓ, AlN, BN, CN), carbides (e.g. SiC, BC, TiC), oxy-nitrides (e.g. SiOxNy), oxy-carbides (e.g. SiOxCy), carbon-nitrides (e.g. SiCxNy, TiCxNy), and oxy-carbon-nitrides (e.g. SiOxCyNz). Similarly, multinary dielectrics thin films like Si—Al—N, Si—B—N, Si—Ge—N, Si—Ti—N, Si—Al—C, Si—B—C, Si—Ge—C, Si—Ti—C, Si—Al—C—N, Si—Ge—C—N, Si—B—C—N, Si—Ti—C—N, etc. Similarly, nitrides, carbides, carbon-nitrides, oxy-carbon-nitrides can be used as suitable films of one or more of the following elements: titanium, zirconium, hafnium, vanadium, niobium, tantalum, chromium, molybdenum, tungsten, silicon, germanium, aluminum, and boron. This includes high entropy carbides.

Thermo-Compression Bonding (TCB) may be performed with solid metals like copper or gold, requiring temperatures of 300° C. to 500° C., high forces (e.g. >10 MPa), adhesion or barrier layers, and bond films of at least 500 nanometers thick. The advantage of metals is the high thermal conductivity (e.g. 100-400 W/m-K) allowing for thicker films while maintaining a low thermal resistance. TCB applicability benefits from a reduction in temperature to below 300° C. and force below 10 MPa for diamond integration. Process temperature and force reduction for TCB can benefit from improved smoothness, flatness, and cleanliness of the metal surfaces. Improved smoothness, flatness, and cleanliness also benefits a reduction in film thickness. Furthermore, coefficient-of-thermal expansion (CTE) matching of the diamond and semiconductor will allow a further thickness reduction of the metal films. As such, the similar CTE for silicon and diamond are very beneficial for a further (bond) film thickness reduction. Similar as described previously for PAB, various cleaning, anneal, planarization, activation, and treatment methods may be used. Furthermore, similar as described previously for PAB, adhesion (e.g. Ti), or barrier (e.g. Ni—V, or TiN) layers may be used. Bond films may be copper, gold, aluminum, silver, tungsten, or molybdenum. Thin film deposition is typically performed by electrodeposition, electroless deposition, sputtering, CVD, thermal evaporation, or a combination. Copper film thickness used for TCB to bond a semiconductor substrate to a diamond substrate may be 5 micrometers or less, 2 micrometers or less, 1 micrometer or less, 500 nanometers or less, preferably 250 nanometers or less, even more preferred 100 nanometers or less. Silver film thickness used for TCB may be 2 micrometers or less, 1 micrometer or less, 500 nanometers or less, preferably 250 nanometers or less, even more preferred 100 nanometers or less. Gold film thickness used for TCB may be 1 micrometer or less, 500 nanometers or less, preferably 250 nanometers or less, even more preferred 100 nanometers or less, even 50 nanometers or less. In some implementations the grain size and grain orientation are controlled to improve bond strength (e.g. nanotwinned (111) copper). Surface contaminants like oxides may be removed by wet and dry cleaning. In some implementations, surface contamination (e.g. oxides) is removed by a plasma, a beam, a fluxless vapor (e.g. formic acid vapor or anhydrous HF vapor) or atomic layer etch with halogens (e.g. HF, Cl₂). In some implementations, the bond metal (e.g. copper) is passivated by another metal at the surface (e.g. Au, Ag, Pd, etc.). In some implementations, the metal surface is passivated by an atmospheric plasma (e.g. a He plasma containing nitrogen).

In transient liquid phase bonding (TLPB) part of the material melts, the low melting phase (lower melting point materials for example and without limitation tin or indium), and diffuses into or reacts with a solid material, the high melting phase (higher melting point material such as for example and without limitation Cu, Ni, Ag, Au), to form a single or multi-phase material with a higher melting point (by way of example and not by way of limitation containing Cu6Sn5, Cu3Sn1, Ni3Sn3, Au1Sn1, Ag3Sn1, Ag2ln1, etc.) than the low melting phase. Example materials may be specific compositions of Cu—Sn, Ni—Sn, Ag—Sn, Au—Sn, Ag—In, and Au—In. The advantage of TLPB may be the compliance of the liquid during bonding, the reduced roughness requirements, and the high thermal conductivity (e.g. 100 W/m-K). TLPB with Ag and In, or Au and In, may be performed at temperatures below 200° C. with very little force (e.g. <1 MPa) which makes both these examples very suitable for the integration of diamond with a semiconductor by bonding (TLPB). In some implementations 2000 nanometers of a thin silver film deposited onto silicon may be bonded (e.g. at 180° C. with a force of <1 MPa) with a 1000 nanometers of a thin indium film deposited onto SCD. Subsequently the bonded pair may be annealed for 2 hours for further mixing of silver and indium. In some implementations 1000 nanometers of a thin silver film deposited onto silicon may be bonded (e.g. at 180° C. with a force of <1 MPa) with a 500 nanometers of a thin indium film deposited onto SCD. Subsequently the bonded pair may be annealed for 2 hours for further mixing of silver and indium. In some implementations 1425 nanometers of a thin silver film deposited onto silicon may be bonded (e.g. at 180° C. with a force of <1 MPa) with a 1000 nanometers of a thin indium film deposited onto SCD. Subsequently the bonded pair may be annealed for 2 hours for further mixing of silver and indium. In some implementations the atomic ratio of silver and indium may be around Ag-to-In equals 2-to-1. In some implementations a silver film with a Ti adhesion and Ni barrier layer may be deposited onto silicon, and a stack of indium on silver on Ni on Ti may be deposited on SCD. Similar process conditions may be applied for gold-indium, yet with a focus on different atomic ratios of Au-to-In. In some implementations the Au-to-In atomic ratio may be equal to 1.2. In some implementations the Au-to-In ratio may be equal to 1.0. In some implementations the Au-to-In ratio may be equal to 2.1. The final Au—In bondline thickness may be 1000 nm or less, 500 nm or less, 250 nm or less, preferably 150 nm or less, even more preferred 100 nm or less. Similar to what was described previously for TCB (and PAB), various cleaning, anneal, planarization, activation, and treatment methods may be used. Furthermore, similar as described previously for PAB, adhesion (e.g. Ti), or barrier (e.g. Ni—V, or TiN) layers may be used. Bond films may be copper, nickel, gold, or silver on one surface, and tin, indium, or a stack of indium on gold or indium on silver on the other surface. Thin film deposition is typically performed by electrodeposition, electroless deposition, sputtering, CVD, thermal evaporation, or a combination. In some implementations the grain size and grain orientation are controlled to improve TLPB. Surface contaminants like oxides may be removed by wet and dry cleaning. In some implementations, surface contamination (e.g. oxides) is removed by a plasma, a beam, a fluxless vapor (e.g. formic acid vapor or anhydrous HF vapor) or atomic layer etch with halogens (e.g. HF, Cl₂). In some implementations, the bond metal (e.g. indium) is passivated by another metal at the surface (e.g. Au, Ag, etc.). In some implementations, the metal surface is passivated by an atmospheric plasma (e.g. a He plasma containing nitrogen).

Solder or eutectic bonding may use similar materials as for conventional (eutectic) soldering, yet now in thin film form. In some implementations elemental (e.g. indium) solder may be used. In some implementations non-eutectic solder (e.g. lead-based Sn36Pb37, or lead-free SAC compositions) may be used. In some implementations eutectic solder based on Sn, In, or Sb (e.g. specific compositions of Ag—In, Au—In, Au—Sn, Cu—Sn) may be used. The film thickness may be 1000 nm or less, 500 nm or less, 250 nm or less, preferably 150 nm or less, even more preferred 100 nm or less. Similar to what was described previously for TCB (and PAB), various cleaning, anneal, planarization, activation, and treatment methods may be used. Furthermore, similar as described previously for PAB, adhesion (e.g. Ti), or barrier (e.g. Ni—V, or TiN) layers may be used. Thin film deposition is typically performed by electrodeposition, electroless deposition, sputtering, CVD, thermal evaporation, or a combination. In some implementations the grain size and grain orientation may be controlled to improve solder/eutectic bonding. Surface contaminants like oxides may be removed by wet and dry cleaning. In some implementations, surface contamination (e.g. oxides) may be removed by a plasma, a beam, a fluxless vapor (e.g. formic acid vapor or anhydrous HF vapor) or atomic layer etch with halogens (e.g. HF, Cl₂). In some implementations, the bond metal (e.g. indium) may be passivated by another metal at the surface (e.g. Au, Ag, etc.). In some implementations, the metal surface may be passivated by an atmospheric plasma (e.g. a He plasma containing nitrogen).

In some implementations sintering may be used to bond diamond to the semiconductor material. For example, sintering with silver (paste) may be used. In another example, sintering with copper (paste) may be used. Sintering may be done at temperatures below 250° C., either with minimal force (<1 MPa), or high force (e.g. >10 MPa). The final bondline thickness may be 50 microns, or 10 microns. The sintered layer may be porous or dense. The sintered layer may have a thermal conductivity over 100 W/m-K, even over 150 W/m-K. Both the diamond and semiconductor surface may be metallized prior to sintering to improve bond strength upon sintering. Metal layers of copper, silver, or gold may be used in contact with the sinter paste. Adhesion (e.g. Ti), or barrier (e.g. Ni—V) may be used. The paste may be screen printed, or dispensed.

Placement of dies, e.g. diamond dies, may be performed with a pick and place, e.g. a flip chip die bonder, e.g. onto a temporary carrier or onto the target semiconductor wafer or onto the target semiconductor die. In some implementations, placement may be performed by micro-transfer printing (MTP). In some implementations diamonds may be placed by MTP onto the target semiconductor wafer or die, and bonded by a polymer, or adhesive. In other implementations diamonds may be placed by MTP onto the target semiconductor wafer or die in a process similar to PAB, where both one or both surfaces are cleaned, activated, hydrated, bonded, and annealed. In other implementations, die self-alignment based on liquid may be combined with MTP.

The thin films for SAB, ADB, and PAB may be covalent, ionic, or metallic, amorphous or nanocrystalline. The crystallinity of the thin films may be improved by annealing, e.g. rapid thermal annealing, or laser annealing. The thin films may be 1-5 nanometers thick, 10-50 nanometers thick, or even 100 nanometers thick. The thin films may be elemental or contain two or more elements. Furthermore, the thin films may be porous or dense. The thin films may be electrically conductive or electrically resistive. The thermal conductivity of the thin films can have electron and phonon contributions or mainly phonon contributions. The thin films may absorb and adsorb species, e.g. water. Generally, thin films may be electrically resistive, where the latter is especially beneficial for hybrid bonding with through-diamond-vias (TDV), but in some implementations the thin film may be electrically conductive (e.g. TiN). In some implementations the thin films may be produced as a step in the production of the integrated circuit devices, for example as part of the top insulation layer of the integrated circuit device (e.g. BEOL).

The thin metallic films for TCB, TLPB, and solder/eutectic bonding may be amorphous, nanocrystalline or polycrystalline. The crystallinity of the thin films may be improved by annealing, e.g. rapid thermal annealing, or laser annealing. The thin films may be 1-5 nanometers thick, 10-50 nanometers thick, 100-500 nanometers thick, or even 2000 nanometers thick. The thin films may be elemental or contain two or more elements. Furthermore, the thin films may be porous or dense.

As discussed above, after bonding, thin films may become integrated into an interfacial layer between the semiconductor substrate and diamond substrate after bonding. The interfacial layer may be 4000 nm thick or less, 1000 nm thick or less, 500 nm thick or less, 250 nm or less, 150 nm thick or less, 100 nm thick or less, 50 nm or less, preferably 25 nm thick or less, or even 10 nm thick or less, or even 5 nm thick or less, thickness may vary depending on the type of bonding process used. The interfacial layer may have a fairly consistent composition through its thickness, may have a distinct region with a different composition at the interface formed by the bonding surfaces, or may change its composition from one substrate to the next due to the use of more than one film composition.

Bonding for SAB and ADB may be performed in ultra-high vacuum (UHV). Bonding for PAB, TCB, TLPB, eutectic/solder bonding, and polymer bonding may be performed in a low vacuum, air, dry air, or a controlled environment, e.g. dry oxygen, nitrogen, argon, or forming gas.

The resulting diamond-silicon die stack combination may subsequently be packaged with conventional packaging methods, such as chip-on-wafer-on-substrate (CoWoS by TSMC) or other methods, e.g., Foveros by Intel or Saint by Samsung. Packaged IC devices with bonded SCD substrates as described herein may be operated at a higher power or clock rate than otherwise identical IC devices running at the same temperature without the bonded SCD substrate or may be operated at a similar power yet lower operating temperature, or both higher power and lower temperature.

It is noted that bonding techniques, such as the above-described SAB, ADB, PAB, TCB, TLPB, solder/eutectic bonding, and polymer bonding may also be used to bond part or all of a heat sink (cooling technology) to the back side of the SCD thermal management material. This heat sink can be made out of silicon, diamond, graphite, silicon carbide, low expansion alloys, copper, or aluminum. For a heat sink made of a metal, such as copper, an interface material of the same or similar metal may be used in the bonding technique, e.g., as in modified SAB or in ADB instead of semiconductor material. Alternatively, the heat sink may be bonded to the SCD material without a separate interface material between SCD and the heat sink. The heat sink can be designed for various cooling scenarios, e.g. air cooling, liquid cooling, cold plate cooling, immersion cooling, one-phase cooling, two-phase cooling, microchannel cooling, spray cooling, jet cooling, or impingement cooling.

Direct bonding of SCD substrate to IC dies with thin semiconductor layers greatly facilitates lateral spreading of heat generated in the IC die, which greatly reduces, and may even eliminate hot spots in the IC. The absence of a TIM between the SCD and the IC places the heat spreading efficiency of the SCD close to the integrated circuit components in the IC die. Similarly, thinning the semiconductor wafer prior to bonding greatly improves the heat spreading efficiency. Reducing hot spots increases the power capacity of the IC device and thereby increases the device speed, allowing for running the IC device cooler, or a combination of both.

FIG. 8D schematically illustrates hybrid bonding with the SAB process. The hybrid bonding process generally follows the same process as shown in FIG. 8A. Unlike the previous bonding process, here, the semiconductor substrate 802 includes a non-homogenous material region 816 such as a metal region. The non-homogenous region 816 includes a non-homogenous material bonding surface 816b on the bonding surface of semiconductor substrate 802b. In some implementations a barrier region 818, such as a semiconductor nitride region may surround the non-homogenous region and act as a diffusion barrier against the non-homogeneous material. The SCD substrate 810 includes a non-homogeneous material region 817 such as a metal region. The non-homogenous region 817 includes a non-homogenous material bonding surface 817b on the bonding surface 810b of SCD substrate 810. Similar to FIG. 8A, the bonding surfaces are treated with beams of atoms or ions 805 in a UHV environment to remove remaining contaminants and create reactive dangling bonds and amorphize a few nanometers of each bonding surface (1-5 nm). Typically, Argon atoms or ions are used. Amorphizing the bonding surfaces 802b. 810b, 816b, 817b avoids issues with lattice mismatch. The treated surfaces are then brought into contact and (optionally) subject to bonding pressure (force) under UHV, as indicated by the black arrows. The UHV environment allows for a few minutes to bring the surfaces into contact and form strong (covalent) bonds. As shown, the non-homogeneous material region in the semiconductor substrate 816 is aligned along an axis with the non-homogeneous material region in the SCD substrate 817 so that the two non-homogeneous regions bond with each other. In some implementations the lateral alignment between the two non-homogeneous regions may be less than 10% deviation from the non-homogeneous region's lateral size, e.g. for a 1 um non-homogeneous region size, an alignment accuracy of 100 nm or better. The bonding may be done at relatively low temperature, e.g., in the range of room temperature (about 25° C.). The resulting bonds are free of a significant thickness of intermediate material. As a result of the amorphization, there may be an interface region of amorphous material between the bulk crystalline semiconductor and the bulk crystalline SCD with an interface between the two amorphous materials. The amorphous material region is, however, quite thin, e.g., 2-10 nm in thickness, which is quite insignificant compared to a semiconductor wafer 1-10 μm thick. The resulting bonds are also quite strong. For example, in the case of a silicon semiconductor substrate bonded to SCD, the bonds have a pull strength of 10's MPa, e.g. 80 MPa. This is advantageous as stronger bonding generally improves thermal performance. Temperature might be used during bonding, after bonding, e.g. in an anneal step, or both, to improve the contact area between both non-homogeneous (metal) regions and the resulting electrical conductivity at and around the interface of both non-homogeneous regions and to improve bond strength in general.

FIG. 8E schematically illustrates an example of hybrid bonding with the modified SAB process. As with conventional SAB, the respective bonding surfaces of a semiconductor substrate 802 and SCD substrate 810 including the non-homogeneous regions bonding surfaces 816b and 817b are cleaned of contaminants. As with conventional SAB, the bonding surfaces are treated with beams of atoms or ions 805 in a UHV environment. However, atoms or ions 807 of a bonding material are included with the treatment beams 805 and incorporated into the bonding surfaces, as indicated by the dotted lines. Typically, the bonding atoms or ions may be the same as those of the bulk semiconductor substrate 802. For example, silicon atoms may be used when bonding a silicon substrate to an SCD substrate. The bonding surfaces 802b, 801b, 816b, 817b are then brought into contact under UHV and subject to bonding pressure (force). The bonding atoms incorporated into the bonding surfaces assist in forming bonds between the amorphous regions at the bonding surfaces. The amorphous material region 812 can still be quite thin, however, e.g., 2-10 nm in thickness. Another way of incorporating thin films for the hybrid SAB bonding is by thin film deposition prior to surface activation, e.g., by atomic layer deposition, sputtering, pulsed layer deposition, MOCVD, MBE, CVD, or electron beam deposition. One or both surfaces might be deposited with a thin film prior to SAB. Furthermore, the semiconductor substrate including a non-homogenous material region and SCD substrate including a non-homogeneous material region might be treated (surface activation) prior to thin film deposition in addition to surface activation of the film surfaces prior to SAB. The thin film(s) formed by either the bonding atoms or ions from the modified SAB bonding process or the separate deposition of thin film(s) might be electrically conductive or electrically resistive. For electrically conductive thin films, the electrical conductivity upon bonding, anneal, wave source treatment (e.g. laser, or acoustic), or a combination, may be significantly reduced in the semiconductor regions. For electrically resistive thin films, the electrical conductivity upon bonding, anneal, wave source treatment (e.g. laser, or acoustic), or a combination, may be significantly enhanced in the non-homogeneous (metal) regions.

FIG. 8F schematically depicts hybrid bonding with an ADB process. Generally, the respective bonding surfaces 802b, 810b including the non-homogeneous regions bonding surfaces 816b and 817b are cleaned of contaminants outside of an ADB tool. Next, UHV thin films 811, 813 (e.g., 1-5 nm) of metal (e.g., Ti) or semiconductor (e.g., Si or AlN) or oxide are formed on the bonding surfaces 802b, 810b, including the non-homogeneous regions bonding surfaces 816b and 817b e.g., by sputtering of atoms, ions, neutral species, or clustered species 809. The thin films 811, 813 may be amorphous or crystalline films. Because the films 811, 813 are freshly created in UHV they bond together very effectively by bringing the surfaces into contact with each other and subjecting them to little or no pressure (force). The resulting structure has two interfaces, one between the semiconductor substrate 802 and an interfacial bonding layer 815 and another between the interfacial bonding layer 815 and the SCD substrate 810. However, the interfacial layer can be quite thin, e.g., 25 nm or less in thickness. Thin films might be used that are either electrically conductive, or electrically resistive. For electrically conductive thin films, the electrical conductivity upon bonding, anneal, wave source treatment (e.g. laser, or acoustic), or a combination, may be significantly reduced in the semiconductor regions. For electrically resistive thin films, the electrical conductivity upon bonding, anneal, wave source treatment (e.g. laser, or acoustic), or a combination, may be significantly enhanced in the non-homogeneous (metal) regions.

In addition to hybrid bonding by SAB, modified SAB, or ADB, PAB or polymer bonding may be used for hybrid bonding to diamond with through-diamond vias (TDVs). PAB hybrid bonding with TDVs follows a process similar to ADB as shown in FIG. 8F but includes a plasma activation, and a hydrophilicity enhancement step after deposition of the thin films.

Conventional PAB hybrid bonding refers to the simultaneous bonding of dielectric (matrix) and metal bond (pads or vias) in one bonding step. Hybrid bonding is the way forward for advanced packaging (e.g. 2.5D, and 3D) requiring very flat (e.g. roll-off <1 nm per micrometer) and smooth (e.g. RMS <1 nm, preferably <0.5 nm, even more preferred <0.2 nm) wafers and dies, bonding with minimal/no particles (very stringent cleanliness requirements), and accurate die placement (typically 10% maximum deviation from contact size in lateral placement, e.g. 1 μm contact size means 100 nm lateral placement accuracy, and very tight angular control, especially for large dies). Hybrid bonding results in a reduction of bondline thickness, thinner packages, smaller pitches (below 10 μm, even below 1 μm, even below 0.5 μm), and as a result faster, more reliable, and more power-efficient chips. Typically, SiO₂, SiNₓ, and SiCN thin films are used for bonding, and annealing at between 200° C. and 350° C. is required after bonding. In addition, optimized copper plating processes (e.g. controlled grain orientation, nanoscale grain size, nanotwinning) improve bonding in the conductive via regions, and dicing often relies on either laser or plasma dicing (e.g. to reduce particles). Higher alignment accuracies are achieved today with wafer-to-wafer bonding than with (collective or sequential) dies-to-wafer bonding. A typical process flow starts after BEOL with CVD of the bonding dielectric (e.g. SiCN), optionally followed by annealing for film densification, patterning of via holes through dielectric, damascene deposition of barrier followed by copper fill (e.g. electrochemical deposition), planarization of bonding dielectric with slight copper recess (dishing, which fills up upon annealing), cleaning, plasma activation (without oxidizing the copper pads or sputtering the copper onto the dielectric), optionally cleaning, optionally hydration, alignment, bonding at room temperature, and annealing to strengthen the (dielectric) bond and make electrical connection between copper pads. Process cleanliness and alignment are key. Similar process flows may be applied for different hybrid bonding methods, e.g. SAB, modified SAB, ADB, and polymer bonding.

It should be understood that thermal management benefits not only from heat spreaders, and heatsinks, but may also benefit from thermal interconnects, e.g. vias, e.g. inside the semiconductor substrate, IC device layer, IC interconnect layers, bond layers, heat spreaders, and heat sinks. Typically, thermal vias are made out of copper. Other materials suitable for thermal vias may be silver, gold, silicon carbide, diamond, carbon nanotubes, or graphene.

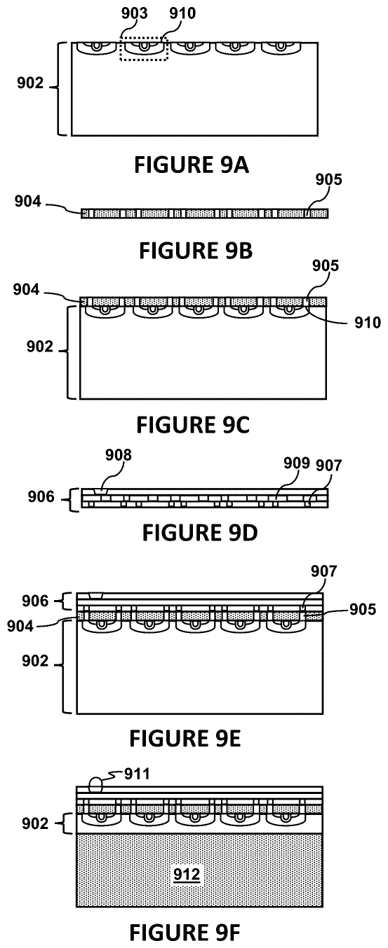

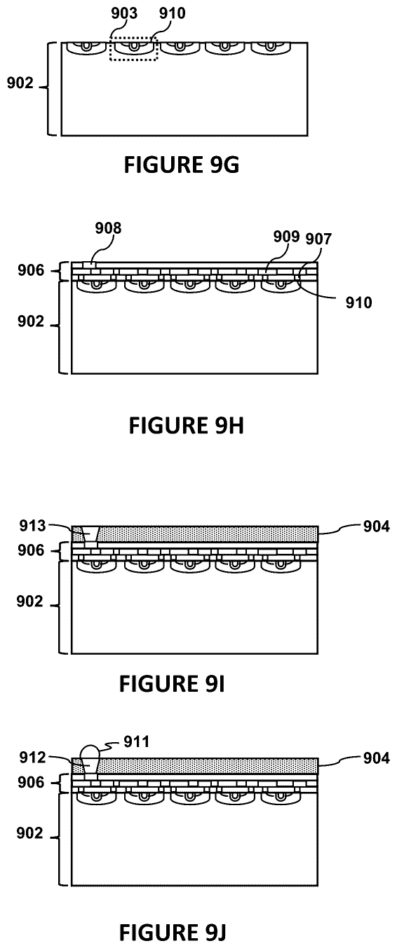

FIG. 9A-9F illustrate an example of fabrication of a composition of matter having a semiconductor material having integrated circuit devices formed therein bonded to a single crystal diamond substrate having through diamond vias (TDV) according to aspects of the present disclosure. It should be noted that at various stages in the fabrication temporary carriers may be used (not shown in FIG. 9A-9F). Hybrid bonding enables more efficient placement of the single crystal diamond heat spreader. In this implementation the single crystal diamond material is placed as close to the IC devices in the semiconductor substrate as possible by locating the single crystal diamond substrate underneath part or all of the chip interconnect. As shown in FIG. 9A semiconductor substrate 902 includes one or more IC devices 903 formed in the semiconductor substrate. The IC devices 903 may include frontside electrical contacts 910 on a front side major surface of the semiconductor substrate 902. These electrical contacts 910 may include one or more selected from power rails, inputs, and outputs (e.g. signals) for the IC devices.

After the IC devices 903 and frontside electrical contacts 910 have been formed a layer of diamond 904 may be disposed on the front side major surface of the semiconductor substrate 902 to act as a heat spreader. This stage of processing is sometimes referred to as “front end of line” (FEOL). The diamond layer may be patterned with vertical electrical contacts 905 aligned with the frontside electrical contacts of the IC devices. In some implementations, the diamond layer may be formed by deposition of diamond film, e.g., single crystal, polycrystalline, microcrystalline or nanocrystalline diamond film, e.g., by CVD. The diamond film may be formed at low-temperature, while still having high-thermal conductivity polycrystalline diamond film growth. The thickness range of the diamond film may be between 10 nm and 500 nm. The resulting diamond layer may then be etched through a mask to produce a pattern of openings that are aligned with the frontside electrical contacts 910. The openings may then be filled with conductive material, e.g., a metal such as copper, tungsten, cobalt, ruthenium, platinum, iridium, nickel, molybdenum, chromium, gold, titanium, or titanium nitride, or some other conductive material, such as doped polycrystalline silicon to form the vertical electrical connections 905. In alternative implementations, the diamond layer 904 may be formed from a single crystal diamond (SCD) substrate that is bonded to the front side major surface of the semiconductor substrate 902. In some implementations, the diamond layer 904 may include a pattern of unfilled openings or voids. The size, shape, and spacing of the openings may be selected to provide the layer of diamond with a dielectric constant that is lower than that of diamond, while still providing sufficient thermal conductivity for heat spreading.

FIG. 9B depicts an example of a single crystal diamond (SCD) substrate that may be used as the layer of diamond 904 configured to act as the heat spreader close to the one or more IC devices 903 in the semiconductor substrate 902 according to aspects of the present disclosure. The SCD substrate 904 here, includes one or more conductive through diamond vias (TDV)s that act as the vertical electrical connections 905. By way of example, the SCD substrate 904 may be die-sized, e.g., 0.5 mm×0.5 mm to 33 mm×26 mm up to wafer-sized, e.g., 150 mm, 200 mm, or 300 mm diameter. The SCD substrate may be a thin SCD substrate for example and without limitation the SCD substrate may be between 10 and 300 nanometers in vertical thickness. A tradeoff for diamond vertical thickness between heat spreading capacity and resistive losses has been recognized. Thinner diamond substrates have a lower heat spreading capacity thus reducing the usefulness of the diamond substrate as a heat spreader. On the other hand, if diamond is too thick, the longer aspect ratio of the conductive vias makes them susceptible to resistive losses. Thus, in some implementations an SCD substrate having a vertical thickness of 30 nanometers may be used. The TDVs may be formed in the SCD substrate by any suitable method, for example and without limitation, mask patterning (e.g., with nitride hard mask) followed by either dry etching (e.g., reactive ion etching (RIE) with chlorine (CI)), wet or oxidative etching. Alternatively, the TDVs may be formed by lasers, e.g. by laser ablation (dry or waterjet), or two-photon-absorption-induced photo-electrochemical etching. The TDVs 905 may have a diameter of less than 50 microns, preferably less than 10 microns, more preferably less than 5 microns, even more preferably below 1 micron, even more preferably below 500 nm, even more preferably below 100 nm. TDVs of less than 1 micron may be referred to as Nano-through diamond vias (NTDV)s. The TDVs 905 may be made conductive by plating and/or filling with conductive materials. For example, and without limitation, the TDVs may be filled with copper or a refractory metal, in some implementations the vias may be deposited with a metal barrier followed by a metal seed layer such as titanium and filled with copper or a refractory metal e.g., tungsten.

The methods used to create SCD substrates, whether with or without TDVs, varies depending on the SCD substrate thickness from techniques similar to Soitec's SmartCut and EVG's NanoCleave (IR laser debond) to thinning by abrasive or etching techniques. SCD substrates, whether with or without TDVs, might be supported by temporary carriers. Such thinning may be accomplished, e.g., by using one or more of the following techniques: abrasive techniques, grinding, lapping, chemical mechanical polishing (CMP), polishing (wet or dry), wet etching, dry etching, laser ablation, film transfer techniques similar to Soitec's SmartCut more generally called HCut, or laser debonding. The thinning process may be facilitated by, e.g., a temporary carrier with a temporary adhesive, specialized pads or tapes, or the TAIKO process. Instead of temporary carriers with temporary adhesives, mobile electrostatic carriers might be used, or temporary carriers might be bonded by SAB, ADB, PAB, or TCB

As depicted in FIG. 9C the SCD substrate 904 is bonded to the semiconductor substrate 902 via hybrid bonding. Additionally, one or more of the conductive TDVs 905 may be bonded to one or more corresponding electrical contacts of the IC devices 910 via hybrid bonding. The hybrid bonding techniques that may be used here are discussed above with respect to FIG. 8D, FIG. 8E, and FIG. 8F, e.g. SAB, modified SAB, ADB, and PAB Although in this example, the TDVs 905 are filled with conductive material prior to bonding, in alternative implementations, the TDVs may be formed after bonding, e.g., by patterned etching and electrochemical deposition of copper.

After the diamond layer 904 with vertical electrical connections is formed, a chip interconnect layer may be formed on top of it. Formation of portions of the interconnect layer 906 that are closer to the devices 903 is sometimes referred to as a middle end of line (MEOL) process. Formation of portions of the interconnect layer 906 that are closer to external contacts 908 is sometimes referred to as a back end of line (BEOL) process. FIG. 9D shows a separate interconnect layer 906 according to aspects of the present disclosure. In the illustrated example, the interconnect layer 906 is a separate (open) circuit that includes conductive vertical interconnects 907 and lateral conductive regions 909. The interconnect layer 906 may be made of a dielectric material, such as silicon oxide, porous silicon oxide, silicon oxy-carbide, organosilicate glass, carbon doped oxide dielectrics composed of Si, C, O, and H (SiCOH), silicon nitride, or even diamond. The separate (open) circuit may be supported by a temporary carrier. In alternative implementations, the interconnect layer may be formed from a deposited layer of material, e.g., in a dep-etch-dep process. In some implementations, e.g., when the interconnect layer is made of diamond, the interconnect layer 906 may include a pattern of unfilled openings or voids. The size, shape, and spacing of the openings may be selected to provide a desired dielectric constant and heat spreading properties. Additionally, the semiconductor chip interconnect may include the external contacts 908, which may receive (copper) pillars, micro-bumps, or pads 911. The conductive vertical interconnects 907 may be conductive vias formed in the chip interconnect layer material of the semiconductor chip interconnect by any known via formation means (e.g., etching, laser ablation, etc.). The vias may be plated and or/filled with a conductive material to make them conductive. In some implementations the vias may be filled with copper or a refractory metal and in some alternative implementations the vias may be deposited by a metal barrier layer followed by a metal seed layer such as titanium and filled with copper or a refractory metal e.g., tungsten. The lateral conductive regions may be regions of conductive material, for example metalized regions or regions of (doped) polycrystalline silicon. Metalized regions may be formed by deposition of a dielectric material, etching of the regions to be metalized and filling of those regions with the metal. The metal may be for example and without limitation copper or a refractory metal. While the implementation shown depicts a layer having conductive vertical interconnects and a layer having lateral conductive regions, aspects of the present disclosure are not so limited, and the semiconductor chip interconnect may be a complex stacked interconnect having two or more layers of conductive vertical interconnects and two or more layers of horizontal conductive regions. Vertical interconnects and lateral conductive regions may exist in the same layer. Alignment of the semiconductor chip interconnect to the SCD substrate and the TDVs to the conductive vertical interconnects may be performed on a wafer level with less than 20 nm variation in alignment from center between at least one of the one or more conductive vertical interconnects and at least one of the one or more conductive TDVs that will undergo hybrid bonding.

Processing at the stage shown in FIG. 9E is an example of integration of a diamond layer prior to BEOL. FIG. 9E shows bonding of the chip interconnect 906 to the diamond substrate 904 via hybrid bonding. Additionally, at least one of the one or more conductive TDVs 905 are bonded to at least one of the one or more vertical interconnects 907 by hybrid bonding. In some implementations the backside of the semiconductor substrate 902 may then be thinned to 10 microns or less. Next as shown in FIG. 9F the back side of the semiconductor substrate 902 may be bonded to an SCD substrate 912.

Alternatively, a layer of diamond may be deposited on the back side of the semiconductor substrate 902. Attachment of the SCD substrate to the thinned semiconductor substrate may be performed by the process shown in, for example FIGS. 7E through 7F for a single semiconductor device. Additionally, a heatsink may be attached to the backside diamond heat spreader by for example and without limitation the method discussed above with respect to FIG. 7G. Additionally heat sinks may be attached to one or more minor surfaces (e.g., sides) of the diamond heat spreader (not shown).

As an example, FIGS. 9G-9J illustrate an example of introducing a diamond layer after BEOL. As shown in FIG. 9G semiconductor substrate 902 includes one or more IC devices 903 formed in the semiconductor substrate. The IC devices 903 may include frontside electrical contacts 910 on a front side major surface of the semiconductor substrate 902. These electrical contacts 910 may include one or more selected from power rails, inputs, and outputs (e.g. signals) for the IC devices. After the IC devices and frontside electrical contacts have been formed, one or more chip interconnect layers 906 may be formed on top of it, as shown in FIG. 9H. As noted above, formation of portions of the interconnect layers 906 that are closer to external contacts 908 is sometimes referred to as a back end of line (BEOL) process. In the illustrated example, the interconnect layer 906 is a separate (open) circuit that includes conductive vertical interconnects 907 and lateral conductive regions 909. The interconnect layer 906 may be made of a dielectric material, such as silicon oxide, porous silicon oxide, silicon oxy-carbide, organosilicate glass, carbon doped oxide dielectrics composed of Si, C, O, and H (SiCOH), silicon nitride, or even diamond. The interconnect layer material may optionally include voids to adjust the dielectric constant. In some implementations, the interconnect layer may be formed from a deposited layer of material, e.g., in a dep-etch-dep process.

The conductive vertical and lateral interconnects may be made of any suitable electrically conductive material, including copper (Cu), tungsten (W), Cobalt (Co), Ruthenium (Ru), platinum (Pt), Iridium (Ir), Nickel (Ni), Molybdenum (Mo), Chromium (Cr), and Gold (Au). The pitch of the vertical interconnections may range from 10's of nm near IC devices 903 to below 10 μm, even below 1 μm near external connections 908. The thickness of the interconnections may range from 10's nm near transistors to below 10 μm, even below 1 μm near external connections with thickness/width aspect ratios for the horizontal metal regions (metal wires) of typically 2.0-3.0, even as high as 5. The number of interconnect layers 906 may range from 1 up to 19 or more.

After the BEOL processing, e.g., after the interconnect layers 906 have been formed, a diamond layer 904 is then disposed on the surface of the uppermost interconnect layer. The diamond layer may be an SCD substrate bonded to the uppermost interconnect layer, or a diamond film formed on the uppermost interconnect layer. Openings may be formed in the diamond layer, e.g., at locations corresponding to external contacts 908 and filled with conductive material 913 to provide electrical contact from the outside. In some implementations solder bumps, (copper) pillars, micro-bumps, or pads 913 may be formed on the surface of the conductive material 913, as part of post-BEOL processing.

In some implementations the TDVs may be created after bonding a thin SCD substrate to the semiconductor material having integrated circuit devices, followed by creating via holes in the SCD and filling them with conductive material, followed by either bonding to semiconductor chip interconnects or growing semiconductor chip interconnects on top of the SCD substrate. In some implementations the thin SCD substrate will be further thinned and smoothened after bonding to the semiconductor material having integrated circuit devices prior to creation of TDVs.

In another implementation, SCD substrates with via holes may be bonded to the semiconductor material having integrated circuit devices, followed by filling the via holes with conductive material. In yet another implementation, SCD substrates are bonded to semiconductor chip interconnect first, followed by TDV creation, followed by bonding to the semiconductor material having integrated circuit devices. In yet another implementation (as illustrated in FIG. 9A-F), SCD substrates with created TDVs are bonded to the semiconductor material having integrated circuit devices.

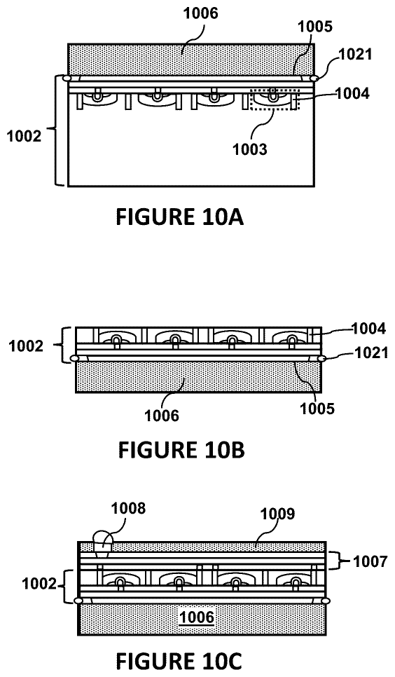

FIG. 10A depicts a semiconductor substrate composition 1002 having IC devices 1003 formed therein. The IC devices 1003 here include backside electrical contacts 1004 buried in the semiconductor substrate composition 1002. The backside electrical contacts 1004 may be implemented in the form of buried power rails, power vias, direct contacts to source and drain, or similar. As shown, the semiconductor substrate composition 1002 includes a semiconductor chip interconnect and a layer of diamond that acts as heat spreader 1006. The layer of diamond may be deposited on or bonded to a major surface 1005 of the semiconductor substrate including the chip interconnect. The bonding may be performed by, for example, SAB, modified SAB, or ADB processes as discussed above with respect to FIGS. 8A, 8B or 8C. Alternatively, the bonding may be performed by PAB, or polymer bonding. Signal lines of the semiconductor chip interconnect may be connected at various connection points 1021, e.g. around the perimeter of the semiconductor interconnect stack or by means of vertical interconnect vias through the signal interconnect stack, device layer, semiconductor substrate, and power interconnect stack to keep the SCD heat spreader 1006 uncompromised. The connection points may be made via solder bumps, (copper) pillars, micro-bumps, or pads, e.g. on the power interconnect side of the overall stack. In some alternative implementations the signal lines of the semiconductor interconnect may be connected through the SCD heat spreader, e.g., using TDVs. In such implementations, hybrid bonding may be used to attach the SCD to the stack. In implementations where the signal lines exit the stack by means of vertical interconnects exiting on the power interconnect side of the semiconductor substrate the SCD may be attached to the stack by standard bonding, e.g. SAB, ADB, PAB, or polymer bonding.

In an alternative implementation instead of bonding an SCD substrate to the semiconductor substrate composition 1002 a seed layer of AlNₓ, SiNₓ, SiOxNy, SiCN, cBN, or Ir may be deposited on the surface of the semiconductor substrate composition 1005. A diamond film 1006 (which may be for example and without limitation nanocrystalline, micro-crystalline, or polycrystalline) may then be grown over the seed layer to form a diamond heat spreader. These diamond layers may be formed at low-temperature, while still having high-thermal conductivity polycrystalline diamond film growth. The thickness range of this diamond film may be between 10 nm and 500 nm when TDVs are present in the film, or 50 micrometers to 800 micrometers when no TDVs are present in the film. In some implementations the diamond film may then be patterned, etched, and plated and/or filled with an electrically conductive material to form conductive vias (TDVs). FIG. 10B shows thinning the backside of semiconductor substrate composition 1002 to expose the backside electrical contacts 1004. The substrate composition 1002 is flipped frontside down to prepare for the creation of a backside interconnect on the now exposed backside major surface. It should be noted that at various stages in the fabrication temporary carriers may be used (not shown in FIG. 10A-10C).

FIG. 10C shows formation of backside chip interconnect 1007 on the backside major surface of the semiconductor substrate composition 1002. The backside chip interconnect 1007 may be formed by a similar process that created the front side interconnect, for example and without limitation the damascene process. A backside SCD substrate 1009 may be bonded to the exposed major side of the backside interconnect 1007. Direct bonding of the backside SCD substrate 1009 to the backside interconnect 1007 may be performed via SAB or ADB as discussed with respect to FIGS. 8A, 8B and 8C. Alternatively, bonding may be performed by PAB or polymer bonding. Subsequently, TDVs 1008 may be created. In some implementations the backside SCD substrate may include one or more TDVs 1008 configured to be bonded with the external contact of the semiconductor backside chip interconnect 1007, in this implementation the backside SCD substrate with the conductive TDVs is directly bonded with the semiconductor chip interconnect and the external contact respectively using hybrid bonding. Similarly, in some implementations the frontside SCD substrate heat spreader 1006 may include one or more TDVs bonded to external contacts on the front side interconnect via hybrid bonding. Similar to as discussed above with the front side heat spreader the backside SCD may instead be film grown over the backside interconnect 1007.

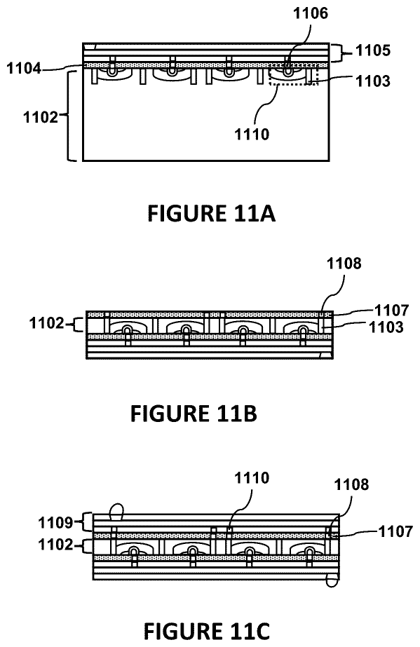

FIGS. 11A-11C depict a method of making a composition of matter including an integrated circuit device having backside and frontside SCD heat spreaders bonded to the semiconductor substrate underneath corresponding backside and frontside interconnects, respectively, according to aspects of the present disclosure. As shown in FIG. 11A, the semiconductor substrate 1102 includes IC devices 1110 formed therein. The IC devices include one or more front side electrical contacts and one or more backside electrical contacts 1103. The one or more backside electrical contacts may be implemented in the form of buried power rails, power vias, direct contacts to source and drain, or similar. A SCD substrate heat spreader 1104 having one or more TDVs 1106 is bonded to the semiconductor substrate 1102 in a manner similar to that discussed above with FIGS. 9B-9E. One or more TDVs are bonded to one or more corresponding frontside electrical contacts of the IC device through hybrid bonding. The semiconductor substrate 1102 and SCD substrate heat spreader 1104 may be of similar lateral dimensions to each other, e.g., die-sized, or wafer-sized. As discussed above a semiconductor chip interconnect 1105 is bonded to the SCD substrate heat spreader 1104 with at least one of the one or more TDVs 1106 bonded to at least one of the one or more conductive vertical interconnects of the semiconductor chip interconnect 1105. The semiconductor substrate 1102 is then thinned similarly to discussed above with respect to FIG. 7D.

The composition is then flipped and a backside SCD substrate heat spreader 1107 is bonded to the backside major surface of the semiconductor substrate 1102 as shown in FIG. 11B. The backside SCD substrate heat spreader includes one or more backside TDVs 1108. At least one of the backside TDVs 1108 may be bonded to at least one of the backside electrical contacts 1103 through hybrid bonding as discussed with FIGS. 8D, 8E, or 8F. The backside SCD substrate heat spreader may be of similar vertical thickness to frontside SCD substrate heat spreader for example and without limitation the backside SCD substrate heat spreader may be between 10 and 300 nanometers in vertical thickness. In some implementations the backside SCD heat spreader may be 30 nanometers in vertical thickness. The SCD backside substrate heat spreader 1107 may be of similar lateral dimensions to the semiconductor substrate 1102 and SCD substrate heat spreader 1104. The backside SCD substrate heat spreader 1107 may undergo wafer to wafer bonding and alignment between the backside TDVs 1108 and the corresponding backside electrical contacts 1103 may be less than 10 nm off center. In some implementations a pick and place machine may be used to place the SCD substrate heat spreader and the alignment between the conductive TDVs, and backside electrical contacts may be less than 100 nm off center. It should be noted that at various stages in the fabrication temporary carriers may be used (not shown in FIG. 11A-11C).

Next, as shown in FIG. 11C a backside semiconductor chip interconnect 1109 is bonded to the exposed backside major surface of the SCD substrate heat spreader 1107 via hybrid bonding. Similar to the frontside semiconductor interconnect, the backside interconnect may include one or more backside conductive vertical interconnects 1110, one or more lateral conductive regions and one or more external contacts. The semiconductor interconnect may be a complex stacked interconnect with two or more layers of lateral conductive regions and/or conductive vertical interconnects. Vertical interconnects and lateral conductive regions may exist in the same layer. At least one of the TDVs 1108 are bonded to at least one of the vertical interconnects 1110 of the backside chip interconnect 1109. Similar to the bond between the SCD substrate and the semiconductor substrate, the backside SCD substrate heat spreader 1107 in some implementations may undergo wafer to wafer bonding with the semiconductor interconnect 1109 and alignment between the at least one of the backside conductive TDVs 1108 and the at least one of the vertical conductive interconnects may be less than 10 nm off center. In some implementations a pick and place machine may be used to place the SCD substrate heat spreader and the alignment between the backside conductive TDVs and the corresponding vertical interconnects may be less than 100 nm off center.

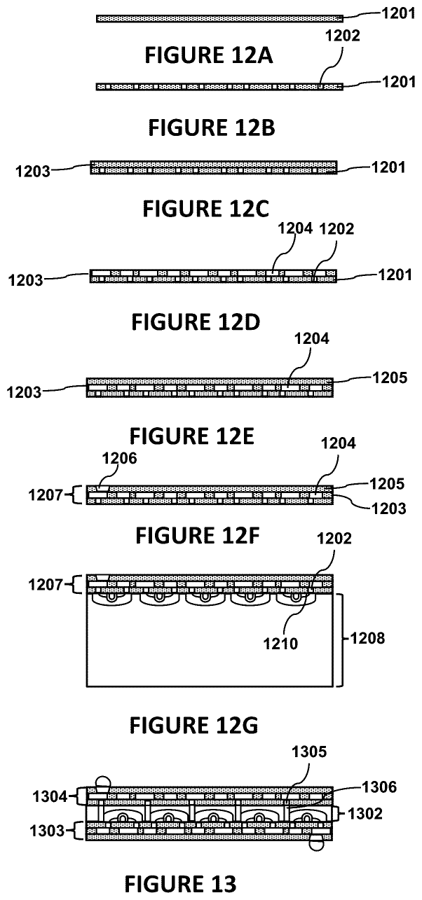

FIGS. 12A-12G depict a method of making a composition of matter of semiconductor substrate having a diamond chip interconnect directly bonded to a major surface according to aspects of the present disclosure. As shown in FIGS. 12A-12F a diamond interconnect may be created from single crystal diamond substrates. FIG. 12A shows the initial SCD substrate 1201 used in the formation of the diamond chip interconnect. The SCD substrates used in this implementation may be between 10 and 300 nanometers in vertical thickness and may be die-sized or wafer-sized lateral dimensions. In some implementations the diamond interconnect may be 30 nanometers in vertical thickness. As shown in FIG. 12B through diamond vias 1202 are formed in the SCD wafer 1201. These TDVs 1202 may become conductive vertical interconnects in the diamond chip interconnect. The TDVs may be formed in the SCD substrate by any suitable method, for example and without limitation, mask patterning (e.g. with nitride hard mask) followed by either dry etching (e.g. RIE with CI), wet, or oxidative etching. Alternatively, the TDVs may be formed by lasers, e.g. by laser ablation (dry or waterjet), or two-photon-absorption-induced photo-electrochemical etching. The vias may be less than 50 microns diameter, preferably less than 10 microns, more preferably less than 5 microns in diameter, even more preferably below 1 microns in diameter, even more preferably below 500 nm, even more preferably below 100 nm. The TDVs 1202 may be plated and/or filled with a conductive material. For example, and without limitation, the conductive material may be copper or a refractory metal. In some examples the TDV may have a metal barrier layer followed by a seed layer titanium deposited in the via and then be plated and filled with a second metal such as copper or tungsten. Next as seen in FIG. 12C, a second SCD layer 1203 is bonded to a major surface of the first SCD layer 1201. The second SCD layer 1203 may be bonded by either SAB or ADB bonding as discussed with FIGS. 8A-8C. Alternatively, bonding may be performed by PAB or polymer bonding. It should be noted that at various stages in the fabrication temporary carriers may be used (not shown in FIG. 12A-12G).

After bonding the first SCD layer 1201 to the second SCD layer 1203, as shown in FIG. 12D, lateral conductive regions 1204 may be formed in the second SCD layer 1203. To form the lateral conductive regions, the second SCD substrate may be masked with a suitable masking material for example and without limitation a photoresist mask may be applied to the exposed major surface of the second SCD layer. A pattern may be applied to the mask and the mask may be developed. After the mask is developed with the pattern an etchant (for example chloride etchant) may be applied to the surface of the diamond and dry etching may be performed. After etching the patterned mask may be removed with a suitable solvent and/or by CMP. A metal may then be deposited over the exposed surface of the diamond composition filling the valleys created by the etchant. Excess metal on the un-etched hills may be removed by CMP. In some alternative implementations the material removal may be performed via laser ablative processing. In yet other alternative implementations laser processing may be used to generate conductive non-diamond carbon (e.g. graphite) traces in the diamond. These conductive non-diamond carbon traces may be used instead of metal in the lateral conductive regions. The thickness of the interconnections may range from 10's nm near transistors to below 10 μm, even below 1 μm near external connections with thickness/width aspect ratios for the horizontal metal regions (metal wires) of typically 2.0-3.0, even as high as 5. The number of interconnect layers may range from 1 up to 19 or more.

As shown in FIG. 12E a third SCD substrate 1205 may be bonded to the major surface of the second SCD layer 1203. In implementations where the diamond chip interconnect is a complex layered interconnect the third SCD layer may include one or more conductive vias which will be conductive vertical interconnects between diamond layers. In such a case the layers will be hybrid bonded with each other and at least one conductive via will be bonded to at least one lateral conductive region. Similarly, the step discussed with FIG. 12D may be repeated over the third SCD layer to create an additional layer of lateral conductive regions. These steps may be repeated multiple times to create a complex diamond interconnect spanning many layers with portions of lateral conductive regions connected between layers by vertical interconnects. Vertical interconnects and lateral conductive regions may exist in the same layer. In some implementations the diameter of vertical interconnects may increase as the layers increase away from the semiconductor substrate. For example, and without limitation, the vias of the vertical interconnects closest to the semiconductor substrate may have a diameter of 10-30 nanometers while the layer farthest from the semiconductor substrate may have a diameter of 100-300 nanometers. The resulting diamond chip interconnect may be in the form of a stack of two or more layers of SCD with lateral conductive regions 1204 formed in a different layer than the vertical interconnects, e.g., TDVs 1202. It should be noted that aspects of the present disclosure are not limited to separate layers for lateral conductive regions and vertical interconnects and depending on the layout of the diamond interconnect there may be layers that include both vertical interconnects and lateral conductive regions in the same layer.

Once a sufficient number of layers with vertical interconnects and lateral conductive regions have been created, external contacts may be generated in the outermost diamond layer. As shown in FIG. 12F the diamond chip interconnect is a simple interconnect requiring only a single layer of horizontal conductive regions thus in the third SCD layer 1205 external contacts 1206 may be formed. The external contacts may be formed by masking, patterning and development of the mask and dry etching. The etched layer may be metallized, and the excess metal not located in the etched valleys may be removed by CMP.

After formation of the diamond chip interconnect 1207 the interconnect may be bonded to a semiconductor substrate 1208 having IC devices formed therein. The IC device having at least one or more electrical contacts 1210 on the major surface of the semiconductor substrate 1208. The semiconductor substrate 1208 and the diamond portion of the diamond chip interconnect may be bonded via hybrid bonding as discussed in FIG. 8D, FIG. 8E, or FIG. 8F. Likewise at least one of the conductive vertical interconnects 1202 is bonded to at least one of the electrical contacts 1210 via hybrid bonding. As with the other implementations alignment is a factor in proper conductive contact, the diamond chip interconnect may be made from diamond dies and placed via a pick and place machine, the alignment of the conductive vertical interconnects may be 150 nm or less off center. In some implementations the diamond chip interconnect may be wafer sized and bonding may be performed wafer to wafer with an alignment of 10 nm or less off center. In an alternative implementation the diamond chip interconnect may be created partially or completely by film deposition of diamond instead of bonding SCD, e.g. dep-etch-dep.

In an alternative implementation the diamond chip interconnect may be created from a solid single crystal diamond substrate using 3-dimensional laser processing. The laser may be focused at different depths in the diamond to create vertical conductive vias in the diamond and the laser may move laterally to create lateral conductive regions in the diamond. The laser processed regions of the diamond may be converted to conductive carbon to create a solid single crystal diamond interconnect of conductive circuits inside a resistive matrix. Alternatively, solid single crystal diamond substrate may be processed by a laser to have diamond removed to create vertical open vias and lateral open regions (e.g. two-photon-absorption-induced photo-electrochemical etching) and subsequently have the voids injected (e.g. by plating) with a more electrically conductive material than carbon such as copper, gold, silver, tungsten, cobalt, ruthenium, platinum, iridium, nickel, molybdenum, chromium or any alloy thereof. It should be understood that various combinations of bonding of SCD, deposition of diamond films, and via creation methods may be used to fabricate a diamond chip interconnect.

In some implementations of the present disclosure the addition of air gaps in the diamond may be used to locally decrease the relative permittivity of the diamond layer. Diamond has a relatively high dielectric constant of 5.7, while air has a lower dielectric constant of around 1.0. Diamond has high mechanical robustness which can tolerate the formation of voids within the material without breaking, thus in some implementations, laser processing (e.g. ablation or two-photon-absorption-induced photo-electrochemical etching) may be used to create air gaps in diamond layers to decrease the local dielectric constant in areas near electrical conductors. For example, and without limitation, a laser process may be used on a diamond heat spreader to form voids near electrically conductive areas in the semiconductor interconnect or semiconductor substrate.

FIG. 13 depicts a composition of matter having a semiconductor substrate 1302 directly bonded to a frontside diamond interconnect 1303 and a backside diamond interconnect 1304 according to aspects of the present disclosure. Here the front side diamond interconnect may be formed and directly bonded to the semiconductor substrate as discussed with FIGS. 12A-12G. Unlike in FIGS. 12A-12G the semiconductor substrate 1302 here includes IC devices that have both front side electrical contacts and backside electrical contacts 1306. The backside diamond interconnect 1304 may be formed in a similar manner to the interconnect described with FIGS. 12A-12F. The semiconductor substrate 1302 may be thinned as discussed above and then the backside diamond interconnect may be bonded to the semiconductor substrate with at least one vertical interconnect 1305 bonding to at least one backside electrical contact 1306 via hybrid bonding. Additionally, heatsinks may be attached to the top and or sides of the diamond interconnects to further improve cooling efficiency. In an alternative implementation the diamond chip interconnect may be created partially or completely by film deposition of diamond instead of bonding SCD, e.g. dep-etch-dep.

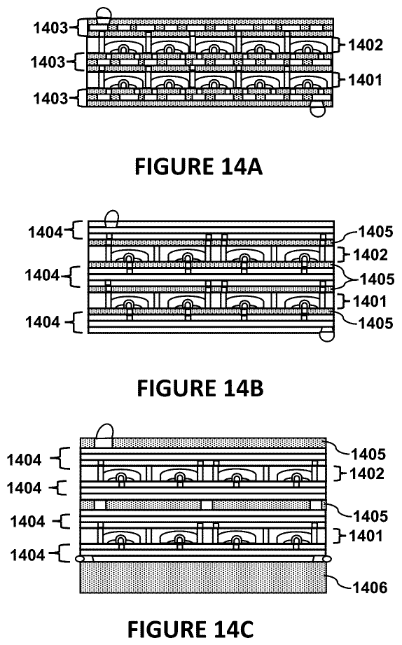

FIGS. 14A-14C depict 3-dimensional stacked IC devices according to aspects of the present disclosure. The improvement in heat spreading of the diamond layers may allow for the stacking of IC devices which was previously not considered possible due to heat constraints. FIG. 14A shows a first semiconductor substrate having IC devices 1401 and a second semiconductor substrate having IC devices 1402 and diamond interconnect structures 1403. The first semiconductor substrate having IC devices 1401 can be incorporated as shown in FIG. 14A, or incorporated upside down with frontside electrical connections facing the frontside electrical connections of the second semiconductor substrate 1402. Similarly, the second semiconductor substrate having IC devices 1402 can be incorporated as shown in FIG. 14A, or incorporated upside down with backside electrical connections facing the backside electrical connections of the first semiconductor substrate 1401. The first semiconductor substrate having IC devices 1401 and a second semiconductor substrate having IC device 1402 are sandwiched between diamond interconnects and are connected together with a diamond interconnect 1403. The diamond interconnects may be formed in a manner described with FIGS. 12A-12G with each semiconductor substrate undergoing hybrid bonding with diamond interconnects to form the 3D stacked structure. The diamond interconnect structures in this 1403 implementation provide interconnection and heat spreading allowing for a more heat efficient 3D stacked architecture. FIG. 14B shows a first semiconductor substrate having IC devices 1401 and a second semiconductor substrate having IC devices 1402 with semiconductor IC interconnects 1404 and an SCD heat spreader 1405 close to the semiconductor substrates of each of the IC devices. The first semiconductor substrate having IC devices 1401 can be incorporated as shown in FIG. 14B, or incorporated upside down with frontside electrical connections facing the frontside electrical connections of the second semiconductor substrate 1402. Similarly, the second semiconductor substrate having IC devices 1402 can be incorporated as shown in FIG. 14B, or incorporated upside down with backside electrical connections facing the backside electrical connections of the first semiconductor substrate 1401. The stacked structure here is formed similar to the structures described in FIGS. 11A-11C with an SCD heat spreader 1405 of the second semiconductor substrate having IC devices 1402 bonded to an interconnect of the first semiconductor substrate having IC devices 1401. Finally, FIG. 14C depicts a first semiconductor substrate having IC devices 1401 and a second semiconductor substrate having IC devices 1402 with a semiconductor interconnect 1404 close to the semiconductor substrates 1401, 1402 and an SCD heat spreader 1405 farther from the semiconductor substrates. The first semiconductor substrate having IC devices 1401 can be incorporated as shown in FIG. 14C, or incorporated upside down with frontside electrical connections facing the frontside electrical connections of the second semiconductor substrate 1402. Similarly, the second semiconductor substrate having IC devices 1402 can be incorporated as shown in FIG. 14C, or incorporated upside down with backside electrical connections facing the backside electrical connections of the first semiconductor substrate 1401. This 3D stacked structure may be formed in similar manner to what is described in FIGS. 10A-10C, except an interconnect of a second semiconductor substrate having IC devices 1402 may be bonded to an SCD heat spreader of the first semiconductor substrate having IC devices 1401. Through-diamond vias may connect the semiconductor interconnects or the interconnects may be connected together on the sides via wire bonds or metal clips, e.g. for thicker diamond. The first semiconductor substrate 1401 having IC devices may have the same type of IC devices or different IC devices than the second semiconductor substrate 1402 having IC devices. For example, and without limitation, the IC devices of the first semiconductor substrate may be configured to be logic devices while the IC devices of the second semiconductor substrate may be configured to be memory devices. In an alternative implementation the diamond chip interconnect may be created partially or completely by film deposition of diamond instead of bonding SCD, e.g. dep-etch-dep.

There are a number of possible combinations of IC devices or ICs that may be created using the stacked architecture illustrated in FIG. 14A, FIG. 14B, or FIG. 14C. Some examples include, but are not limited to microprocessors, microcontrollers, semiconductor memory devices, digital signal processor (DSP) devices, analog signal processing devices, system-on-a-chip (SoC) devices, AI chips, machine learning chips, image processing chips, large language model processing chips, training and/or inference chips for AI, and more. The IC devices may be formed on die of any of a number of different configurations for delivering signal and power including, but not limited to no backside power delivery, backside power delivery without memory on top of logic, backside power delivery with memory on top of logic.

In some implementations one or more logic dies may have backside power delivery, and one or more diamond heat spreaders may be located between the signal interconnect layers and the heatsink, and/or between the thinned semiconductor substrate and the backside power delivery interconnect layers with the backside power delivery interconnect stack facing away from the heatsink. In some implementations one or more logic dies may have backside power delivery, and one or more diamond heat spreaders may be located between the signal interconnect layers and the heatsink, and/or on the side of the external surface of the power delivery interconnect layers with the backside power delivery interconnect stack facing away from the heatsink. In some implementations one or more memory dies may be stacked on top of one or more logic dies with one or more diamond heat spreaders sandwiched between the one or more memory dies and one or more logic dies and/or with one or more diamond heat spreaders between the one or more memory dies and heatsink. In some implementations, the one or more logic dies in the stack of one or more memory dies on top of the one or more logic dies has backside power delivery, optionally with one or more diamond heat spreaders between the thinned semiconductor substrate and the backside power delivery network, optionally with one or more diamond heat spreaders on top of the external face of the backside power delivery network facing away from the heatsink. In some implementations one or more logic dies may be stacked on top of one or more logic dies with one or more diamond heat spreaders sandwiched between the one or more logic dies on top and one or more logic dies on the bottom and/or with one or more diamond heat spreaders between the one or more logic dies on top and heatsink. In some implementations, the one or more logic dies at the bottom in the stack of one or more logic dies on top of the one or more logic dies at the bottom has backside power delivery, optionally with one or more diamond heat spreaders between the thinned semiconductor substrate and the backside power delivery network, optionally with one or more diamond heat spreaders on top of the external face of the backside power delivery network facing away from the heatsink. These stacks of dies with one or more diamond heat spreaders may be part of advanced packages, e.g. 2.5D packages, or 3D packages, e.g. CoWoS, Saint, or Foveros packages. Those skilled in the art may recognize the various stack sequences are possible with e.g. various memory dies, logic dies, and diamond heat spreaders. Furthermore, those skilled in the art may recognize that stacking of dies may be performed with varying orientations of dies, e.g. with signal IC interconnects facing each other, etc. Similarly, those skilled in the art recognize that even when signal IC interconnects are on the opposite side of the power IC interconnects for an IC die, e.g. for backside power delivery, the connection to both the signal IC and power IC outside of the IC die or IC dies stack may be from the same side of the IC die, e.g. by implementation of through vias.

It should be noted that diamond heat spreaders, whether SCD substrates or diamond films, may be created during many different stages of IC device production including front end of line (FEOL), middle end of Line (MEOL), back end of line (BEOL), and after back end of line (after BEOL). The implementations described herein represent different ways to apply diamond heat spreaders during different stages of production as well as different configurations for diamond heat spreaders. Currently the after BEOL implementation such as shown in FIGS. 10C and 14C, having the diamond heat spreader located farther from the semiconductor substrate on top of a semiconductor interconnect may be the simplest to implement as further away from the transistors the diamond can be made thicker, and the diameter of the Through Diamond Vias may be made larger. Although implementations are disclosed herein in which the diamond layer is SCD bonded to a semiconductor die or wafer, the diamond layer may be disposed on the semiconductor other than by bonding SCD. By way of example, the diamond layer may be formed by growing diamond films (e.g., nanocrystalline, micro-crystalline, polycrystalline). As one example, among others, low-temperature, high-thermal conductivity polycrystalline diamond film may be grown on aluminum nitride (AlNₓ), silicon nitride (SiNₓ), silicon oxynitride (SiOxNy), silicon carbon nitride (SiCN), cubic boron nitride (cBN), or iridium (Ir) seed layers formed on the surface of a semiconductor wafer or die, optionally with a diffusion barrier layer underneath, e.g. TiN, TaN, STO, or YSZ. The diamond film may be in a thickness range of 10 nm to 100 nm thick or 100 nm to 500 nm thick or 500 nm to 1000 nm thick, e.g. when the diamond film is located close to the semiconductor substrate. However, the diamond film may be significantly thicker when located farther away from the semiconductor substrate, e.g. 5 microns to 300 microns, depending on the location of the diamond film inside the overall stack.

In some implementations the multiple chiplets that are stacked and assembled in a 2.5D or 3D package incorporating one or more diamond heat spreaders may include one or more GPUs, and one or more high-bandwidth memory (HBM) stacks on top of an interposer. One or more of the chiplets that may be assembled into a chip package including one or more diamond heat spreaders may support one or more of the following units: a compute unit (e.g. GPU, TPU, or NPU), HBM stack, cache memory, control logic, scratchpad memory, interconnects, I/O interfaces, specialized processing units, control logic, power management, security features, etc. In an advanced package, e.g. 2.5D or 3D package, two or more dies (chiplets, or IC devices) may be horizontally interconnected, by a suitable interconnect technology, e.g., by the substrate, a hybrid substrate, one or more redistribution layers (RDL), one or more interposers, or one or more interconnect bridges.

Although certain process sequences are illustrated and described herein, those skilled in the art will recognize that the sequence of stacking (e.g., logic semiconductor, memory semiconductor, diamond layer, IC), via hole creation, and via hole filling can vary tremendously. Furthermore, the size of the TDVs depends partly on the location of the diamond layer in the device stack. The diamond layer may be made thinner and the diameter of the TDVs may be made smaller if the diamond layer is closer to the transistors. Conversely, the further away from the transistors, the thicker the diamond layer, and the larger the diameter of the TDVs may become. For example, forming the diamond layers after BEOL generally involves a thicker diamond layer and a larger pitch and diameter for the vias. Such a configuration is more suitable for SCD dies, and there is less need for SCD wafers.

For some implementations a cost reduction may be desirable, and thinner diamonds (e.g. 300 microns) may be used. However, it may be desirable to keep the height of the coupled diamond and thinned semiconductor stack at a fixed value (e.g. 775 microns), e.g. when matching the height of one or more compute dies (e.g. GPUs) to one or more high-bandwidth-memory (HBM) stacks inside an advanced package, e.g. a CoWoS package. A filler material may be used, e.g. copper, silicon carbide, silicon, etc. The filler materials may be coupled to the diamond heat spreader by any of the methods previously described, e.g. SAB, ADB, PAB, TCB, TLPB, solder/eutectic bonding, and polymer bonding. Similarly, the diamond coupled to the filler material may be coupled to the semiconductor material by any of the methods previously described.

For some implementations a cost reduction may be achieved through the use of rougher diamonds (e.g. Sa<100 nanometers). However, it may be desirable to keep the roughness of the diamond bond surface at a fixed low value (e.g. Sa<0.5 nanometers). A smoothening material may be used, e.g. copper, silicon carbide, silicon, etc. to smoothen rough diamond for bonding. The smoothening material may be coupled to the semiconductor material by any of the methods previously described, e.g. SAB, ADB, PAB, TCB, TLPB, solder/eutectic bonding, and polymer bonding. In some implementations SiCN is used as a smoothening material. SiCN is deposited by PECVD, followed by smoothening, e.g. CMP. An adhesion layer (e.g. Ti), or barrier layer (e.g. TiN) may be used underneath the SiCN. Other smoothening materials may be TiN, TaN, SiNₓ, Al₂O₃, BeO, SiC, amorphous carbon, and diamond-like carbon. In some implementations, a film may be deposited onto a rough diamond surface. Subsequently, the surface may be smoothened, e.g. by CMP. Subsequently, the film may be etched with an etch recipe where the etch rate of both the film material and diamond are (almost) identical (etch selectivity equals 1). The film may be completely removed, and a bare, smooth diamond surface remains. One example is the deposition of SiO₂ by CVD onto rough diamond, followed by CMP, followed by dry reactive ion etching, e.g. reactive ion etching with a mixture of O₂ and SF₆.

According to aspects of the present disclosure, an improvement in cooling and heat-spreading efficiency for semiconductor devices may be realized because diamond has one of the highest thermal conductivities of any material currently characterized. The direct bonding of diamond wafers or dies to semiconductor substrates (e.g., wafers or dies) or formation of diamond films on such substrates in different configurations allows for the improved spread of heat away from heat sensitive IC devices. Implementations such as the interstitial diamond heat spreader between the semiconductor substrate and a semiconductor chip interconnect allow for the spreading of heat even closer to the IC devices which generate most of the heat. Further the integration of the diamond into the interconnect itself may provide the double duty of interconnect and heat spreader thus reducing the overall size of the device while retaining the improved heat spreading ability of SCD directly bonded to the semiconductor substrate.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the items following the article, except where expressly stated otherwise. The appended claims are not to be interpreted as including means-plus-function limitations, unless such a limitation is explicitly recited in a given claim using the phrase “means for.”

What is claimed is:

1. An integrated circuit (IC) with diamond heat spreader, comprising:
a first semiconductor material substrate having a thickness of 100 microns or less, the first semiconductor material having a major surface;
one or more IC devices formed in the semiconductor material substrate proximate the major surface;
one or more diamond layers having a thickness less than 2000 microns disposed on the major surface of the semiconductor material substrate; and
an interfacial region between the one or more diamond layers and the first semiconductor material substrate.

2. The IC of claim 1, wherein the thickness of the first semiconductor material substrate is 10 microns or less.

3. The IC of claim 1, wherein the thickness of the first semiconductor material substrate is 5 microns or less.

4. The IC of claim 1, wherein the thickness of the first semiconductor material substrate is 500 nanometers or less.

5. The IC of claim 1, wherein the thickness of the one or more diamond layers is 1000 microns or less.

6. The IC of claim 1, wherein the thickness of the one or more diamond layers is 300 microns or less.

7. The IC of claim 1, wherein the one or more diamond layers are characterized by a lateral dimension between 4 mm and 300 mm.

8. The IC of claim 1, wherein the first semiconductor material substrate is a Silicon substrate.

9. The IC of claim 1, wherein the first semiconductor material substrate is composed of a material selected from the list consisting of: silicon germanium, gallium nitride, silicon carbide, gallium arsenide, indium phosphide, gallium oxide, aluminum nitride, a IV-IV semiconductor, a III-V semiconductor, a II-VI semiconductor, a I-Ill-VI semiconductor, a I-II-IV-VI semiconductor, a perovskite semiconductor, an oxide semiconductor.

10. The IC of claim 1, wherein the one or more diamond layers include one or more single crystal diamond layers.

11. The IC of claim 1, wherein the one or more diamond layers include a diamond layer that is coupled to the major surface of the first semiconductor material substrate, wherein the interfacial region between the one or more diamond layers and the first semiconductor material substrate contains a metal layer or stack of metal layers having a thickness of 10 micrometers or less, wherein the metal layer or stack of metal layers contains one or more of the following elements: titanium, chromium, copper, gold, silver, nickel, tin, antimony, or indium.

12. The IC of claim 1, wherein the one or more diamond layers include a diamond layer that is coupled to the major surface of the first semiconductor material substrate, wherein the interfacial region between the one or more diamond layers and the first semiconductor material substrate contains a metal layer or stack of metal layers having a thickness of 5 micrometers or less, wherein the metal layer or stack of metal layers contains one or more of the following elements: titanium, chromium, copper, gold, silver, nickel, tin, antimony, or indium.

13. The IC of claim 1, wherein the one or more diamond layers include a diamond layer that is coupled to the major surface of the first semiconductor material substrate, wherein the interfacial region between the one or more diamond layers and the first semiconductor material substrate contains a metal layer or stack of metal layers having a thickness of 1 micrometer or less, wherein the metal layer or stack of metal layers contains one or more of the following elements: titanium, chromium, copper, gold, silver, nickel, tin, antimony, or indium.

14. The IC of claim 1, wherein the one or more diamond layers include a diamond layer that is coupled to the major surface of the first semiconductor material substrate, wherein the interfacial region between the one or more diamond layers and the first semiconductor material substrate is 500 nanometers or less in thickness.

15. The IC of claim 1, wherein the one or more diamond layers include a diamond layer that is coupled to the major surface of the first semiconductor material substrate, wherein the interfacial region between the one or more diamond layers and the first semiconductor material substrate is 100 nanometers or less in thickness.

16. The IC of claim 1, wherein the one or more diamond layers include a diamond layer that is coupled to the major surface of the first semiconductor material substrate, wherein the interfacial region between the one or more diamond layers and the first semiconductor material substrate is 50 nanometers or less in thickness.

17. The IC of claim 1, wherein the one or more diamond layers include a diamond layer that is coupled to the major surface of the first semiconductor material substrate, wherein the interfacial region between the one or more diamond layers and the first semiconductor material substrate is 10 nanometers or less in thickness.

18. The IC of claim 1, wherein the interfacial region includes a layer of silicon oxide, silicon nitride, or silicon carbon nitride.

19. The IC of claim 1, wherein the interfacial region includes a layer of titanium nitride, tantalum nitride, beryllium oxide, aluminum oxide, carbon, amorphous carbon, diamond-like carbon, silicon, amorphous silicon, germanium, or amorphous germanium.

20. The IC of claim 1, wherein the interfacial region includes at least one of oxygen, nitrogen, carbon, and at least one of silicon, germanium, boron, and aluminum.

21. The IC of claim 1, wherein the interfacial region includes at least one of oxygen, nitrogen, carbon, and at least one of Titanium, Zirconium, Hafnium, Vanadium, Niobium, Tantalum, Chromium, Molybdenum, Tungsten.

22. The IC of claim 1, wherein the one or more IC devices include one or more transistors, and one or more electrically conductive interconnects.

23. The IC of claim 1, wherein the first semiconductor material substrate includes one or more IC device dies.

24. The IC of claim 23, wherein the one or more device dies include one or more logic dies, or complementary metal-oxide semiconductor (CMOS) dies, or artificial intelligence (AI) dies, or compute dies, or network dies, or memory dies, or silicon-based device dies, or photonics device dies.

25. The IC of claim 1, wherein the one or more diamond layers includes one or more through diamond vias.

26. The IC of claim 1, further comprising a second semiconductor material substrate coupled to a side of the first semiconductor material opposite the major surface.

27. The IC of claim 1, further comprising a second semiconductor material substrate coupled to a side of the one or more diamond layers opposite the side of the one or more diamond layers disposed on the major surface of the first semiconductor material.

28. The IC of claim 1, wherein the surface of the one or more diamond layers has a smoothness of 0.5 nanometers or less over an area of 10 by 10 micrometers or larger and a lateral dimension larger than 10 millimeters.

29. The IC of claim 1, wherein one of the one or more diamond layers is a single crystal diamond layer with a lateral dimension larger than 10 millimeters.

30. The IC of claim 1, wherein one of the one or more diamond layers is a single crystal diamond layer with a lateral dimension larger than 20 millimeters.

31. The IC of claim 1, wherein the integrated circuit device is part of an advanced chip package with at least one interconnect technology selected from a list consisting of: interposer, interconnect bridge, redistribution layer, and package substrate.

32. The IC of claim 1, wherein the integrated circuit is configured for training and/or inference in artificial intelligence applications.

33. The IC of claim 1, wherein at least one side of the diamond heat spreader has a rough surface that is smoothened with a smoothening material.

34. A method of making an integrated circuit (IC) with a diamond heat spreader comprising:
providing one or more integrated circuit devices in a semiconductor material wherein the IC devices are proximate to a major surface of the semiconductor material; and
bonding one or more diamond layers having a thickness of less than 2000 microns to the major surface of the semiconductor material.

35. The method of claim 34 wherein a bond surface of the one or more diamond layers has a smoothness of 0.5 nanometers or less over an area of 10 by 10 micrometers or larger and a lateral dimension larger than 10 millimeters.

36. The method of claim 34 wherein one of the one or more diamond layers include a single crystal diamond layer with a lateral dimension larger than 10 millimeters.

37. The method of claim 34 wherein one of the one or more diamond layers include a single crystal diamond layer with a lateral dimension larger than 20 millimeters.

38. The method of claim 34 wherein at least one of the one or more diamond layers include a single crystal diamond layer with a thickness less than 50 microns, and a lateral dimension larger than 10 millimeters.

39. The method of claim 34 wherein at least one of the one or more diamond layers include a single crystal diamond layer with a thickness larger than 500 microns.

40. The method of claim 34, wherein the integrated circuit device is part of an advanced chip package with an interconnect technology selected from a list consisting of: interposer, interconnect bridge, redistribution layer, and package substrate.

41. The method of claim 34, wherein the integrated circuit is configured for training and/or inference in artificial intelligence applications.

42. The method of claim 34, wherein the integrated circuit with a diamond heat spreader shares a horizontal plane with a top side of a second IC.

43. The method of claim 34, wherein the first integrated circuit with a diamond heat spreader coupled to a first side of the diamond heat spreader has a filler material bonded to a second side of the diamond heat spreader opposite the first IC; a second IC, wherein a first side of the filler material opposite of a side bonded to the diamond heat spreader shares a horizontal plane with a top side of the second IC.

44. The method of claim 34, wherein at least one side of the diamond heat spreader has a rough surface that is smoothened with a smoothening material.

45. The method of claim 34, wherein the one or more diamond layers include a single crystal diamond layer with a thickness between 100 microns and 2000 microns.

46. The method of claim 34, further comprising depositing a thin film over the semiconductor material and/or the one or more diamond layers before bonding the one or more diamond layers to the semiconductor material.

47. The method of claim 46, wherein the thin film comprises silicon carbon nitride, silicon oxide, or silicon nitride.

48. The method of claim 46, wherein the thin film is metallic and contains one or more of the following: titanium, chromium, copper, gold, silver, nickel, tin, antimony, or indium.

49. The method of claim 46, wherein the thin film contains at least one of oxygen, nitrogen, carbon, and at least one of silicon, germanium, boron, and aluminum.

50. The method of claim 46, wherein the thin film contains at least one of oxygen, nitrogen, carbon, and at least one of Titanium, Zirconium, Hafnium, Vanadium, Niobium, Tantalum, Chromium, Molybdenum, Tungsten.

51. The method of claim 34, wherein the first semiconductor material substrate is a Silicon substrate.

52. The method of claim 34, wherein the first semiconductor material substrate includes a material selected from a list consisting of: silicon germanium, gallium nitride, silicon carbide, gallium arsenide, indium phosphide, gallium oxide, aluminum nitride, a IV-IV semiconductor, a III-V semiconductor, a II-VI semiconductor, a I-Ill-VI semiconductor, a I-II-IV-VI semiconductor, a perovskite semiconductor, an oxide semiconductor.

53. The method of claim 34, further comprising at least one of cleaning, activation, or surface termination of a bond surface of the one or more diamond layers and/or the semiconductor material substrate, wherein the cleaning, activation or surface termination is based on a plasma, ion beam, or atom beam.

54. The method of claim 34 forming one or more through diamond vias in the one or more diamond layers.
